(19) United States
(12) Patent Application Publication
(10) Pub. No.: US 2025/0316593 A1
(43) Pub. Date: Oct. 9, 2025

(54) SEMICONDUCTOR DEVICE, FORMING METHOD AND MEMORY SYSTEM

(71) Applicant: Yangtze Memory Technologies Co., Ltd., Wuhan (CN)

(72) Inventors: Jiajia WU, Wuhan (CN); Zongke XU, Wuhan (CN); Bin YUAN, Wuhan (CN); Wei XU, Wuhan (CN); Zongliang HUO, Wuhan (CN); Fan GONG, Wuhan (CN); Beibei LI, Wuhan (CN); Chao SUN, Wuhan (CN)

(21) Appl. No.: 18/886,982

(22) Filed: Sep. 16, 2024

(30) Foreign Application Priority Data
Apr. 9, 2024 (CN) 202410425181.6

(51) Int. Cl. H01L 23/528; H10B 12/00

(52) U.S. Cl. CPC H01L 23/5283; H10B 12/482; H10B 12/488

(57) ABSTRACT

Semiconductor devices, methods for forming such semiconductor devices, and systems including such semiconductor devices are provided. In one aspect, a semiconductor device includes a first semiconductor structure that includes a stack structure and a transistor. The stack structure includes first conductive layers and second conductive layers that are stacked alternately in a first direction. The transistor is disposed on one side of the stack structure and connected with one of the first conductive layers. The first semiconductor structure further includes a first connection structure extending through the stack structure in the first direction and connected to the second conductive layers.

### CROSS-REFERENCE TO RELATED APPLICATIONS

This application claims the benefit of priority to Chinese Patent Application No. 202410425181.6, filed on Apr. 9, 2024, the disclosure of which is hereby incorporated by reference in its entirety.

### TECHNICAL FIELD

The present disclosure relates to the field of semiconductor technology, and in particular to a semiconductor device, a method of forming a semiconductor device and a memory system.

### BACKGROUND

The 1T1C structure is a common memory cell structure in a dynamic random access memory (DRAM) and composed of a transfer gate and a capacitor. However, with reduction of the size of the capacitor and increase of the number of the layers in a stack, difficulty of fabrication may be further increased, which may cause more difficulty for the capacity of the capacitor to be improved and in turn affect storage performance of the DRAM.

It is to be noted that the information disclosed in the section of Background is only used to facilitate understanding of the background of the present disclosure and may therefore include information that does not constitute prior art known to those of ordinary skills in the art.

### SUMMARY

The present disclosure aims to provide a semiconductor device, a fabrication method thereof and a memory system, which can improve the limitation of applications caused by the great difficulty of fabricating capacitors connected to a vertical transistor at least to some extent.

Other features and advantages of the present disclosure will become apparent through the following detailed description or be learned partially by practicing the present disclosure.

According to one aspect of the present disclosure, a semiconductor device is provided, the semiconductor device including: a first semiconductor structure that includes a stack structure and a transistor, wherein the stack structure includes first conductive layers and second conductive layers stacked alternately in a first direction and the transistor is disposed on one side of the stack structure and connected with one of the first conductive layers; and a first connection structure extending through the stack structure in the first direction and connected to the second conductive layers.

In some implementations, the stack structure further includes: dielectric layers each located between a first conductive layer and a second conductive layer.

In some implementations, the first semiconductor structure further includes: a second connection structure extending through the stack structure in the first direction and connected to the first conductive layers and the transistor respectively.

In some implementations, the stack structure further includes: first isolation layers disposed between the second connection structure and the second conductive layers.

In some implementations, the stack structure includes a plurality of first conductive layers and each of the first conductive layers is connected to the second connection structure.

In some implementations, the first semiconductor structure includes a plurality of sets of the second connection structures and each set of the second connection structures are connected to one of the first conductive layers respectively.

In some implementations, a plurality of sets of the second connection structures are arranged side by side in the second direction perpendicular to the first direction.

In some implementations, the stack structure further includes: a first communication component disposed between the second connection structure and one of the first conductive layers connected with each other.

In some implementations, the stack structure further includes: a second isolation layer disposed between the second connection structure and one of the first conductive layers isolated from each other.

In some implementations, each second connection structure is a pillar structure.

In some implementations, the stack structure further includes: third isolation layers disposed between the first connection structure and the first conductive layers.

In some implementations, the stack structure includes a plurality of second conductive layers connected to the same first connection structure.

In some implementations, the first connection structure is a slit structure extending in a third direction perpendicular to the first direction.

In some implementations, a plurality of sets of the first connection structures are included, the stack structure includes a plurality of the second conductive layers and each of the second conductive layers is connected to one set of the first connection structures.

In some implementations, the stack structure further includes: second communication components disposed between one set of the first connection structures and one of the second conductive layers connected with each other.

In some implementations, the stack structure further includes: fourth isolation layers disposed between one set of the first connection structures and one of the second conductive layers isolated from each other.

In some implementations, a plurality of sets of the first connection structures are arranged side by side in the second direction perpendicular to the first direction.

In some implementations, each first connection structure is a pillar structure.

In some implementations, the first semiconductor structure further includes an isolation structure extending through the stack structure in the first direction and extending in the third direction perpendicular to the first direction.

In some implementations, the transistor includes a vertical transistor, which includes a semiconductor body extending in the first direction, and a gate layer in contact with at least one side of the semiconductor body.

In some implementations, the vertical transistor further includes a source and a drain disposed on the two sides of the semiconductor body in the first direction; and one of the source and the drain is connected to one of the first conductive layers.

In some implementations, it further includes: a word line connected to the gate layer; and a bit line connected to the other of the source and the drain.

In some implementations, it further includes: a metal layer disposed on the other side of the stack structure away from the transistor.

In some implementations, it further includes: a second semiconductor structure located on the side of the first semiconductor structure away from the transistor and hybrid bonded with the first semiconductor structure.

According to another aspect of the present disclosure, a method of forming a semiconductor device is provided, the method including forming a first semiconductor structure, which includes: forming a semiconductor body of a transistor and a stack structure, wherein the stack structure includes first sacrificial layers, dielectric layers, second conductive layers and the dielectric layers stacked alternately in a first direction; forming a first electrode on the semiconductor body, the first electrode being one of the source and the drain of the transistor; replacing the first sacrificial layers with first conductive layers, one of the first conductive layers being connected to the first electrode; and forming a first connection structure connected to the second conductive layers and extending through the stack structure.

In some implementations, forming a first electrode on the semiconductor body further includes: forming a connection hole extending through the stack structure to the semiconductor body in the first direction; forming first isolation layers and second isolation layers at the inner wall of the connection hole, wherein the first isolation layers isolate the second conductive layers and the second isolation layers isolate the first sacrificial layers without connection relationship; and forming a second connection structure in the connection hole, the second connection structure being connected to one of the first sacrificial layers and the first electrode respectively.

In some implementations, forming a connection hole extending through the stack structure to the semiconductor body in the first direction further includes: forming an original slit extending through the stack structure in the first direction.

In some implementations, before forming, in the connection hole, a second connection structure connected to one of the first sacrificial layers and the first electrode respectively, the method further includes: depositing a second sacrificial layer in the connection hole and the original slit.

In some implementations, forming, in the connection hole, a second connection structure connected to one of the first sacrificial layers and the first electrode respectively further includes: removing the second sacrificial layer deposited in the connection hole and filling the connection hole to a form the second connection structure.

In some implementations, forming the semiconductor body of a transistor and a stack structure further includes: forming a third sacrificial layer in contact with the semiconductor body in a second direction perpendicular to the first direction.

In some implementations, the method further includes: removing the second sacrificial layer in the original slit; etching the inner walls of the original slit to form an intermediate slit exposing the first sacrificial layers and the third sacrificial layer; and replacing the first sacrificial layers with the first conductive layers, the method further including replacing the third sacrificial layer with a gate layer.

In some implementations, the method further includes: removing the substrate on the side of the semiconductor body away from the stack structure to expose the semiconductor body; and at the exposed end of the semiconductor body, forming a second electrode connected to a bit line and serving as the other of the source and the drain of the transistor.

In some implementations, the side of the stack structure away from the semiconductor body is a first layer, the side of the stack structure proximate to the semiconductor body is a second layer, and forming connection holes extending through the stack structure to the semiconductor body in the first direction includes: forming a plurality of sets of first sub-holes extending through the first layer in the first direction, one set of the first sub-holes stopping at one of the first sacrificial layers; depositing a conductive material at the bottom of first sub-holes to form first communication components in contact with the first sacrificial layers; and forming second sub-holes extending in the first direction through the first communication components and further through the second layer, the first sub-holes and the second sub-holes being in communication to form the connection holes.

In some implementations, forming first isolation layers and second isolation layers at the inner wall of the connection hole includes: forming first recesses at the first inner wall of the connection hole and depositing second isolation layers in the first recesses for isolation of the first sacrificial layers, wherein the first inner wall is at the first sacrificial layers without connection to any first communication component; forming second recesses at a second inner wall of the connection hole and depositing first isolation layers in the second recesses for isolation of the second conductive layers, wherein the second inner wall is at the second conductive layers.

In some implementations, the method further includes: forming third recesses at the third inner wall of the intermediate slit and depositing third isolation layers in the third recesses for isolation of the first conductive layers so as to form a target slit correspondingly, wherein forming a first connection structure connected to the second conductive layers and extending through the stack structure further includes: filling the target slit to form the first connection structure.

In some implementations, the method further includes: forming a metal layer on the other side of the stack structure away from the transistor through deposition.

In some implementations, the method further includes: forming a second semiconductor structure; and hybrid bonding the first semiconductor structure and the second semiconductor structure.

According to yet another aspect of the present disclosure, a memory system is provided, the memory system including a semiconductor device and a controller, wherein the semiconductor device includes: a first semiconductor structure including a stack structure, a transistor and a first connection structure, wherein the stack structure includes first conductive layers and second conductive layers alternately stacked in a first direction, the transistor is disposed on one side of the stack structure and connected with one of the first conductive layers and the first connection structure extends through the stack structure in the first direction and is connected to the second conductive layers; and a bit line and a word line connected to the transistor respectively, wherein the controller is coupled to the semiconductor device and configured to control the semiconductor device.

In some implementations, the stack structure further includes: dielectric layers each located between a first conductive layer and a second conductive layer.

In some implementations, the first semiconductor structure further includes: a second connection structure extending through the stack structure in the first direction and connected to the first conductive layers and the transistor respectively.

In some implementations, the stack structure includes a plurality of the first conductive layers and each of the first conductive layers is connected to the second connection structure.

In some implementations, a plurality of sets of the second connection structures are included and each set of the second connection structures are connected to one of the first conductive layers respectively.

In some implementations, the stack structure includes a plurality of the second conductive layers connected to the same first connection structure.

In some implementations, the first connection structure is a slit structure extending in a third direction perpendicular to the first direction.

In some implementations, a plurality of sets of the first connection structures are included, the stack structure includes a plurality of the second conductive layers and each of the second conductive layers is connected to one set of the first connection structures.

In some implementations, the transistor includes a vertical transistor, which includes a semiconductor body extending in the first direction and a source and a drain disposed on the two sides of the semiconductor body in the first direction; one of the source and the drain is connected to the first conductive layer; and the other of the source and the drain is connected to the bit line.

In some implementations, the vertical transistor further includes a gate in contact with at least one side of the semiconductor body and the word line is connected to the gate in the second direction perpendicular to the first direction.

In some implementations, it further includes: a metal layer disposed on the other side of the stack structure away from the transistor.

In some implementations, it further includes: a second semiconductor structure located on the side of the first semiconductor structure away from the transistor and hybrid bonded with the first semiconductor structure.

Other features and advantages of the present disclosure and structures and operations of various implementations of the present disclosure are described in detail with reference to accompanying drawings. It is noted that the present disclosure is not limited to the implementations. Such implementations presented herein are only for the purpose of illustration. Based on the teaching included herein, additional implementations will become apparent to those skilled in the art.

### BRIEF DESCRIPTION OF DRAWINGS

Accompanying drawings herein are incorporated in the specification and constitute a part thereof to illustrate implementations according to the present disclosure and, along with the specification, serve to explain the principle of the present disclosure. It is apparent that the figures in the following description are only some implementations of the present disclosure and for those of ordinary skills in the art other figures may also be obtained according to those figures without creative works.

FIG. 1 shows a structural diagram of a memory cell according to some implementations of the present disclosure;

FIG. 2 shows a structural diagram of another memory cell according to some implementations of the present disclosure;

FIG. 3 shows a structural diagram of yet another memory cell according to some implementations of the present disclosure;

FIG. 4 shows a plane view of a memory cell array according to some implementations of the present disclosure;

FIG. 5 shows a structural diagram of a memory system according to some implementations of the present disclosure;

FIG. 6 shows a plane view of another memory cell array according to some implementations of the present disclosure;

FIG. 7 shows a structural diagram of another memory system according to some implementations of the present disclosure;

FIGS. 8-31 show a fabrication process of a semiconductor device according to some implementations of the present disclosure;

FIGS. 32-70 show a fabrication process of a semiconductor device according to some implementations of the present disclosure;

FIG. 71 shows a flow chart of a method of forming a semiconductor device according to some implementations of the present disclosure;

FIG. 72 shows a flow chart of a method of forming a semiconductor device according to some implementations of the present disclosure;

FIG. 73 shows a schematic diagram of a memory system according to some implementations of the present disclosure;

FIG. 74 shows a schematic diagram of a memory card according to an implementation of the present disclosure; and

FIG. 75 shows a schematic diagram of a solid state driver (SSD) according to an implementation of the present disclosure.

### DETAILED DESCRIPTION

Although specific configurations and arrangements have been discussed, it should be understood that they are only for the purpose of illustration. Those of ordinary skills in the art can appreciate that other configurations and arrangements can be used without departing from the spirit and scope of the present disclosure. It is apparent for those skilled in the art that the present disclosure can be used in many other applications.

It is to be noted that “one implementation”, “an implementation”, “example implementation” and “some implementations” in the specification means the described implementation may include certain features, structures or characteristics, but not necessarily every implementation includes the certain features, structures or characteristics. Moreover, such phrases not necessarily refer to the same implementation. In addition, while being described in connection with implementations, certain features, structures or characteristics being implemented in combination with other implementations (no matter whether being described explicitly or not) falls within the scope of knowledge of those skilled in the art.

Generally, terms should be understood at least in part from the usage in their contexts. For example, the term “one or more”, as used herein, may be used to describe any feature, structure, or characteristic in a singular sense or may be used to describe combinations of features, structures or characteristics in a plural sense, depending at least in part upon context. Similarly, terms, such as “a,” “an,” or “the” may be understood to convey a singular usage or to convey a plural usage, depending at least in part upon context.

It should be readily understood that the meaning of “on”, “above” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath”, “below”, “lower”, “above”, “upper” and the like, may be used herein for case of description, so as to describe one element or feature's relationship to another element or feature, as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent materials are added or otherwise disposed. The substrate itself may be patterned. The materials disposed on (e.g., the top of) the substrate can be patterned or can remain unpatterned. Furthermore, the substrate can include a wide array of semiconductor materials, such as silicon, germanium, gallium arsenide, indium phosphide, etc. Alternatively, the substrate can be made from a non-conductive material, such as a glass, a plastic, or a sapphire wafer.

As used herein, the term “layer” refers to a material portion of a region with a thickness. A layer can extend over the entirety of an underlying or overlying structure or may have an extent less than the extent of an underlying or overlying structure. Further, a layer can of be a region of a homogeneous or inhomogeneous continuous structure that has a thickness less than the thickness of the continuous structure. A layer can extend horizontally, vertically, and/or along a inclined surface. A substrate can be a layer, can include one or more layers therein, and/or can have one or more layer thereupon, thereabove and/or therebelow. A layer may include a plurality of layers. For example, a stack can include one or more conductor and contact layers (in which contacts, interconnect lines and/or vias are formed) and one or more dielectric layers.

As used herein, the term “nominal/nominally” refers to a desired or target, value of a characteristic or parameter for a component or a process operation, set during the design phase of production or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10%-30% of the value (e.g., ±10%, ±20%, or ±30% of the value).

As used herein, the term “semiconductor device” refers to a semiconductor device with vertically oriented strings of memory cell transistors (referred to herein as “memory strings,” such as NAND strings) on a laterally-oriented substrate so that the memory strings extend in the vertical direction with respect to the substrate. As used herein, the term “vertical/vertically” means nominally perpendicular to the lateral surface of a substrate.

As used herein, the term “horizontal/horizontally/lateral/laterally” means nominally parallel to a lateral surface of a substrate and the term “vertical” or “vertically” means nominally perpendicular to the lateral surface of a substrate.

As used herein, the term “semiconductor device” may specifically be a 3D memory device that refers to a semiconductor device with vertically oriented strings of memory cell transistors (like NAND memory strings) on a laterally-oriented substrate so that the memory strings extend in the vertical direction with respect to the substrate.

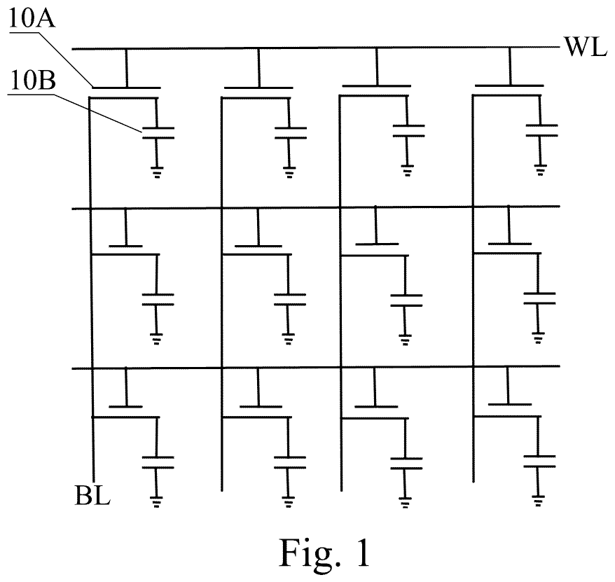

As shown in FIG. 1, in a DRAM process, the memory cell structure of a semiconductor device may be a 1T1C structure, i.e. with one transistor 10A and one capacitor 10B, wherein the transistor 10A is turned on or off under control by a word line (WL), the data in the memory cell is read and written using a bit line (BL) and the capacitor is formed in the form of a vertical one. However, due to the limitation by the process of making a hole, the capacity of the capacitor is hard to increase, the process window is small and in turn the capacity of the memory cell is relatively small.

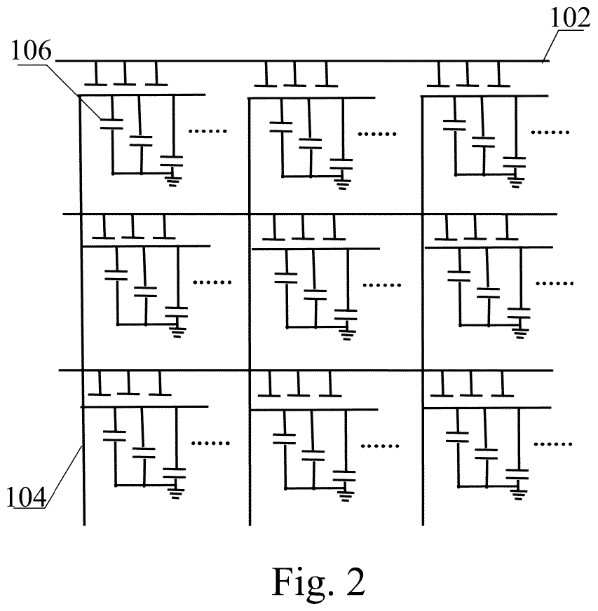

In order to solve one or more of the problems above, a novel design of a memory cell in a semiconductor device is introduced by the present disclosure, in which the existing 1T1C memory structure is changed to an nTnC design, i.e. the memory cell is designed to include n transistors and n capacitors 106 connected to the n transistors in one-to-one correspondence. In some implementations of the present disclosure, FIG. 2 shows a schematic diagram of a semiconductor device having a memory cell structure of the “nTnC” (n=3) design according to some implementations of the present disclosure, wherein each memory cell includes 3 transistors and 3 capacitors and each transistor is connected to a word line 102 and a bit line 104 respectively, so that the memory cell structure based on the “nTnC” design can provide a higher memory density and better reliability.

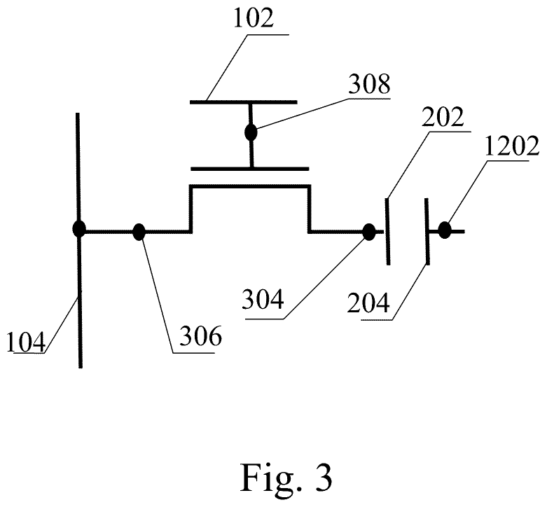

Referring to FIG. 3, the first electrode 304 (one of the drain and the source) of a transistor is connected to the first electrode plate (i.e. the first conductive layer 202) of a capacitor, the second electrode 306 (the other of the drain and the source) of the transistor is connected to a bit line 104, the gate 308 of the transistor is connected to a word line 102 and the second electrode plate, i.e. the second conductive layers 204, of the capacitor is connected to a common electrode 1202.

In some implementations, the gate of a transistor is coupled to a word line, one of the drain and the source of the vertical transistor is coupled to one electrode of a capacitor, the other of the drain and the source of the vertical transistor is coupled to a bit line and the other electrode of the capacitor is coupled to the ground. In some implementations, a capacitor may have a stack structure that will be described in detail hereafter.

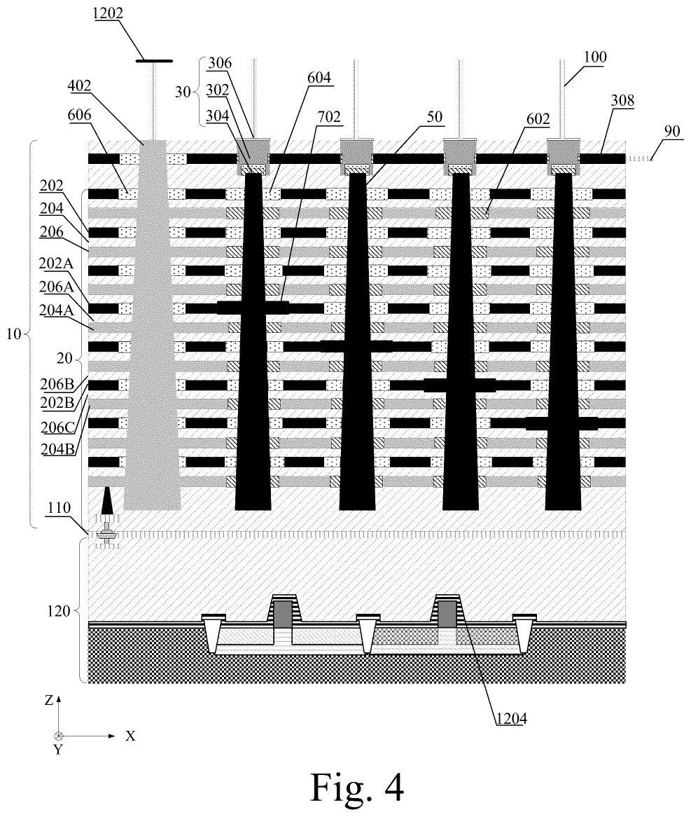

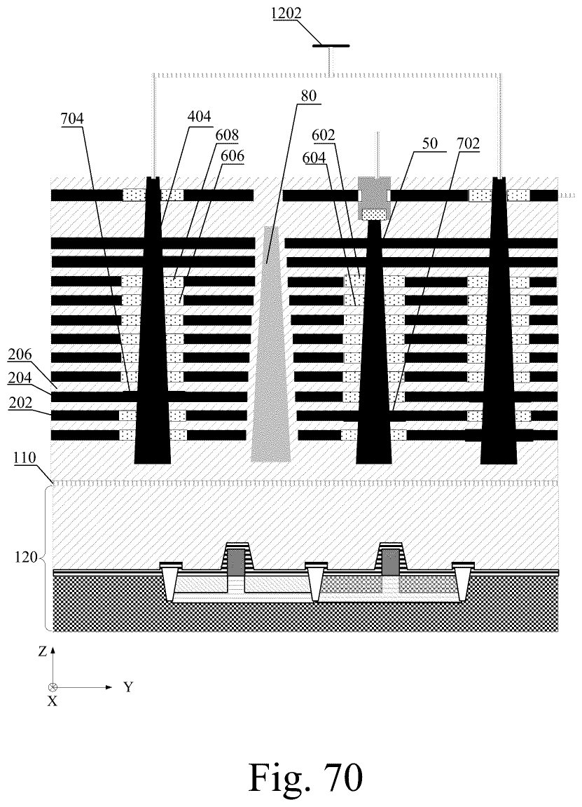

It is to be noted that x, y and z axes are included in FIGS. 4 to 70 to illustrate spatial relationships between components of a semiconductor device. The z direction corresponds to a first direction, the x direction corresponds to a second direction and the y direction corresponds to a third direction. The x direction and the y direction are two directions that are orthogonal to each other in a semiconductor plane and the x direction is the direction of a word line. The z axis is perpendicular to the x and y axes. As used herein, when a substrate (e.g., a substrate) is at the lowest plane in a semiconductor device along the z direction (the vertical direction perpendicular to a xy plane), whether a component (e.g., a layer or a device) is “on”, “above” or “below” another component (e.g., a layer or a device) in the semiconductor device along the z direction may be determined with respect to the substrate of the semiconductor device. In the whole disclosure, the same concepts used to describe spatial relationships are applied.

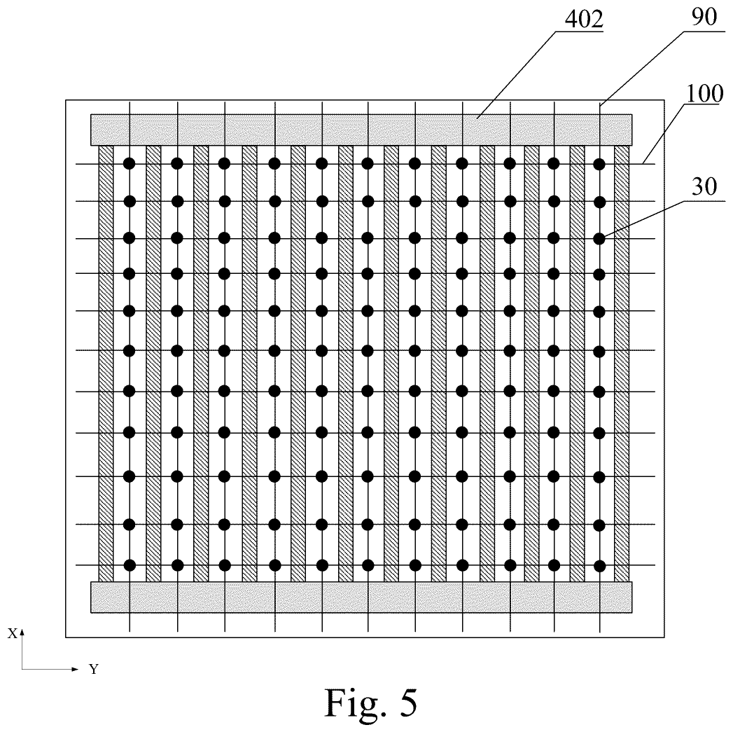

FIG. 4 shows a schematic side view cross-sectional diagram of a semiconductor device according to an implementation of the present disclosure and FIG. 5 shows a schematic planar cross-sectional diagram of the semiconductor device shown in FIG. 4.

As shown in FIG. 4, the semiconductor device includes a first semiconductor structure 10 including a stack structure 20 and a transistor 30. The stack structure includes first conductive layers 202 and second conductive layers 204 alternately stacked in the first direction, and the transistor 30 is disposed on one side of the stack structure 20 and connected with one of the first conductive layers 202.

In the stack structure 20, a first conductive layer 202 (also referred to as a first electrode plate) and a second conductive layer 204 (also referred to as a second electrode plate) adjacent to the first conductive layer 202 form a planar capacitor arranged in stacked planar layers. The stack structure 20 forms a plurality of planar capacitors, each of which has its first electrode plate connected to a transistor, so that a memory cell structure is formed to include a plurality of capacitors and a plurality of transistors. The fabrication process of forming two conductive layers stacked alternately in one direction is simple and easy.

In some implementations, the first conductive layers or the second conductive layers may be formed when forming an original stack structure, or may be formed by forming sacrificial layers first when forming an original stack structure and then replacing the sacrificial layers.

In some implementations, each first conductive layer and each second conductive layer have the same nominal thickness between about 25 nm and about 40 nm, for example, the same thickness between 25 nm and 40 nm, such as 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, any range bounded by any one of the values as a lower limit or any range bounded by any two of the values.

In some implementations, a first conductive layer and a second conductive layer may each include a plurality of conductive layers, for example, a W layer on a TiN layer. In some implementations, the first conductive layers and the second conductive layers may include the same conductive material. In some other implementations, the first conductive layers may include a first conductive material and the second conductive layers may include a second conductive material different from the first conductive material.

In some implementations, as shown in FIG. 4, the stack structure 20 further includes: a dielectric layer 206 between a first conductive layer 202 and a second conductive layer 204.

In some implementations, the dielectric layer may be formed directly when the original stack structure is formed.

In some implementations, the dielectric layer may include a dielectric material including, but not limited to, silicon oxide, silicon nitride, silicon oxynitride or any combination thereof.

In some implementations, each dielectric layer has the same nominal thickness between about 15 nm and about 30 nm, for example, the same thickness between 15 nm and 30 nm, such as 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, any range bounded by any one of the values as a lower limit or any range bounded by any two of the values.

In some implementations, as shown in FIG. 4, the stack structure 20 includes alternating conductive layers and dielectric layers, wherein a conductive layer is the first conductive layer 202 when it, as a first electrode plate, is connected to a transistor, and a conductive layer is a second conductive layer 204 when it, as a second electrode plate, is connected to a common electrode, and two conductive layers have a dielectric layer 206 therebetween. As shown in FIG. 4, when the stack structure is taken as a whole, one end of the stack structure adheres to a metal layer 110, and the other end of the stack structure is proximate to the transistor 30 and disposed parallel with the gate layer 308 of the transistor 30. A dielectric is further filled between the stack structure 20 and the gate layer 308.

As shown in FIG. 4, a first conductive layer 202A, a dielectric layer 206A and a second conductive layer 204A form a planar capacitor; the second conductive layer 204A, a dielectric layer 206B and a first conductive layer 202B form another planar capacitor; and the first conductive layer 202B, a dielectric layer 206C and a second conductive layer 204B form yet another planar capacitor.

In this implementation, a first conductive layer and a second conductive layer act as electrode plates respectively, a dielectric layer and a first conductive layer and a second conductive layer on opposite sides of the dielectric layer constitute a planar capacitor configured to store charges or data. A first connection structure extends through the whole stack structure vertically. A first conductive layer is one side of a planar capacitor, which, via the other side, is connected to the first connection structure as a common electrode. A first conductive layer as the other side of a planar capacitor is configured for connection with a transistor. The capacity of capacitors in a memory cell can be adjusted by adjusting the number of the conductive layers joining a transistor. It facilitates improvement of the memory density when adjusting the number of the conductive layers joining a transistor.

In some implementations, an original stack structure includes therein second conductive layers, dielectric layers, sacrificial layers and dielectric layers stacked alternately, which can be deposited alternately on a substrate through a selective epitaxial growth (SEG) process to form the original stack structure.

In some implementations, the sacrificial layers are replaced to obtain first conductive layers, the sacrificial layers are SIN, and the conductive layers include, but not limited to, W, Co, Cu, Al, polysilicon, doped silicon, silicide or any combination thereof. Or they can be POLY, conductive metal or a metal compound, for example, the conductive layers may be W layers or POLY layers.

In some implementations, as shown in FIG. 4, the first semiconductor structure 10 further includes a first connection structure 402, which extends through the stack structure 20 in the first direction, is connected with second conductive layers 204 and serves as a common electrode connected with the second electrode plates of the planar capacitors. The lead-out common electrode may not occupy the effective area of the first conductive layers and the second conductive layers, so that the resulting planar capacitors can each have a relatively large capacity. Moreover, operations of the fabrication process can be simplified by connecting the common electrode with a plurality of second conductive layers.

In some implementations, the first connection structure 402 is connected with the second conductive layers 204 in the second direction.

In some implementations, as shown in FIG. 4, the stack structure 20 includes a plurality of second conductive layers 204 that are connected to the same first connection structure 402.

In some implementations, an implementation of the first connection structure is a slit structure and as shown in FIG. 4 the slit structure 402 extends through the first conductive layers 202, the dielectric layers 206, the second conductive layers 204 and the gate layer 308 in the first direction. As shown in FIG. 5, the slit structure 402 extends in the third direction.

Referring to FIG. 4, the slit structure 402 leads out as a common electrode 1202 and each slit structure may extend vertically in the y direction to separate the stack structure into memory blocks. In one memory block, first conductive layers, as the first electrode plates, and a plurality of second conductive layers are all connected to the same slit structure.

In some implementations, the slit structure 402 may include any suitable conductive material such as polysilicon, metal (e.g., tungsten (W), copper (Cu), aluminum (Al) or the like), a metal compound (e.g., titanium nitride (TiN), tantalum nitride (TaN) or the like) or silicide.

In some implementations, in order to form the slit structure, during the fabrication process of forming a connection hole, an original slit is formed to extend through the stack structure to the substrate in the first direction; after formation of a second connection structure, the inner walls of the original slit are etched to form an intermediate slit; third recesses are formed at the inner walls of the intermediate slit; depositing third isolation layers in the third recesses isolating the first conductive layers and word lines to form a target slit; and filling the target slit to form the first connection structure 402.

In some implementations, the first connection structure may include any suitable conductive material such as polysilicon, metal (e.g., tungsten (W), copper (Cu), aluminum (Al) or the like), a metal compound (e.g., titanium nitride (TiN), tantalum nitride (TaN) or the like) or silicide.

In some implementations, a slit is formed in the stack structure and the first connection structure is formed by filling the slit, so that the formed first connection structure will not reduce the effective area capacitance between an upper conductive layer and a lower conductive layer.

In some implementations, as shown in FIG. 4, the first semiconductor structure 10 further includes: a second connection structure 50 that extends through the stack structure 20 in the first direction and is connected to the first conductive layers 202 and a transistor 30 respectively.

In some implementations, the second connection structure may be a pillar structure or a plate-like structure.

In some implementations, the second connection structure may include any suitable conductive material such as polysilicon, metal (e.g., tungsten (W), copper (Cu), aluminum (Al) or the like), a metal compound (e.g., titanium nitride (TiN), tantalum nitride (TaN) or the like) or silicide.

In some implementations, in order to form the second connection structure, a connection hole can be formed through an SCT (Use Stair Step (SS) Etch Process to accurately place Contact Hole on each WL) process and may include a first sub-hole and a second sub-hole based on different fabrication processes. The first sub-hole may be formed in a prior process and then the second sub-hole may be formed along the first sub-hole in the post process.

In some implementations, the stack structure 20 includes a plurality of first conductive layers 202 and each of the first conductive layers is connected to a second connection structure 50.

In some implementations, the first semiconductor structure 10 includes a plurality of sets of the second connection structures 50 and each set of the second connection structures 50 are connected to one of the first conductive layers 202 respectively.

In some implementations, in a memory cell architecture having a plurality of conductive layers, there may be a plurality of second connection structures, and a first conductive layer is connected to a transistor through a second connection structure.

In some implementations, as shown in FIG. 4, a first communication component 702 is disposed between the second connection structure 50 and one of the first conductive layers 202 connected to each other.

In some implementations, the first communication component is formed in a process between the fabrication process of the first sub-hole and the fabrication process of the second sub-hole. For example, a conductive material is deposited at the bottom of the first sub-hole to form the first communication component. At this point, the first conductive layers exist as sacrificial layers, and the first communication component is connected to a corresponding sacrificial layer.

In some implementations, the first communication component, the second connection structure and the first conductive layers may include the same conductive material.

In some implementations, in a stack structure having a plurality of sets of first conductive layers, dielectric layers and second conductive layers, one second connection structure or one set of the second connection structures is only connected to one of the first conductive layers. Therefore, with respect to one second connection structure or one set of the second connection structures and for a first conductive layer with a connection relationship therewith, a first communication component needs to be formed at periphery in the horizontal direction and connected to the first conductive layer, while for the first conductive layers and the second conductive layers without any connection relationship therewith, insulating components need to be formed at the periphery. As shown in FIG. 4, an insulating component disposed between a second connection structure 50 and a second conductive layer 204 is designated as a first isolation layer 602 and an insulating component disposed between a second connection structure 50 and one of the first conductive layers 202 isolated from each other is designated as a second isolation layer 604.

Referring to FIG. 4, if there is another first conductive layer and another second conductive layer over the upper side of the first communication component 702, a first isolation layer 602 needs to be formed on the inner walls of the first sub-hole to isolate the second conductive layer 204 and a second isolation layer 604 needs to be formed to isolate the other first conductive layers.

Referring to FIG. 4, if there is provided another first conductive layer and another second conductive layer under the lower side of the first communication component 702, a first isolation layer 602 needs to be formed on the inner walls of the second sub-hole to isolate the second conductive layer 204 and a second isolation layer 604 needs to be formed to isolate the other first conductive layer.

In some implementations, for the first isolation layer and the second isolation layer, oxide (OX) material may be used as the insulating material, may be generated using atomic layer deposition (ALD) and may be aluminum oxide (Al₂O₃). In the stack structure, the first isolation layer and the second isolation layer are formed respectively by depositing ALD OX to isolate the second connection structure from the second conductive layers and the first conductive layers without connection relationship therewith.

In some implementations, a plurality of sets of second connection structures 50 are arranged side by side in the second direction perpendicular to the first direction.

Here, there may be a plurality of sets of second connection structures arranged side by side along the second direction, i.e. the x direction. For each set of second connection structures, there are also a plurality of second connection structures arranged in the third direction, i.e. the y direction, so that the second connection structures form an array structure arranged in the x and y directions respectively. Referring to FIG. 5, a plurality of transistors 30 correspond to the plurality of second connection structures (not shown in the figure) that form an array structure.

In some implementations, each second connection structure 50 is a pillar structure.

In some implementations, as shown in FIG. 4, the stack structure 20 further includes a third isolation layer 606 disposed between the first connection structure 402 and a first conductive layer 202 to isolate the connection structure 402 from the first conductive layer 202.

In some implementations, the third isolation layer may be formed from atomic layer deposition (ALD) oxide (OX) material as an insulating material. The OX may be aluminum oxide (Al₂O₃). In the stack structure, the third isolation layer may be formed by depositing ALD OX to isolate the first connection structure from the first conductive layer.

In some implementations, the transistors 30 may be vertical metal-oxide-semiconductor field effect transistors (MOSFET).

In some implementations, as shown in FIG. 4, the vertical transistor 30 includes a semiconductor body 302 extending in the first direction, which, for example, may have a cube shape exposing its four sides. It can be understood by those skilled in the art that the semiconductor body 302 may have any suitable 3D shape, for example, a polyhedral shape or a cylinder shape. That is, the semiconductor body 302 may have a cross section of a square shape, a rectangular shape (or a trapezoid shape), a circular shape (or an ellipse shape) or any other suitable shape in a plane view (e.g., in a x-y plane). It should be understood that, consistent with the scope of contents of the present disclosure, a semiconductor body having a cross section of a circular shape or an ellipse shape in a plane view still can be considered to have a plurality of sides to make the gate structure contact more than one side of the semiconductor body. The semiconductor body 302 may be formed from a substrate (e.g., by etching or epitaxy) and thus have the same semiconductor material (e.g., crystalline silicon) as the substrate (e.g., a silicon substrate).

In some implementations, as shown in FIG. 4, the vertical transistor 30 further includes a source and a drain (S/D, doped regions, also referred to as a source electrode and a drain electrode) disposed on two sides of the semiconductor body in the first direction (Z direction); one 304 of the source and the drain is connected to a first conductive layer 202 and the other 306 of the source and the drain is connected to a bit line 100.

The source and the drain may be doped with any suitable P-type dopant (e.g., boron (B) or gallium (Ga)) or any suitable N-type dopant (e.g., phosphorus (P) or arsenic (As)).

In some implementations, as shown in FIG. 4, the vertical transistor further includes a gate layer 308 in contact with at least one side of the semiconductor body, and a word line 90 is connected to the gate layer 308 in the second direction perpendicular to the first direction.

The vertical transistor 30 further includes a gate layer 308 in contact with one or more sides of the semiconductor body 302, i.e. the semiconductor body 302 may be at least in part surrounded by the gate layer 308. The gate layer 308 may include a gate electrode. The gate electrode may include any suitable conductive material such as polysilicon, metal (e.g., tungsten (W), copper (Cu), aluminum (Al) or like), a metal compound (e.g., titanium nitride (TiN), tantalum nitride (TaN) or the like) or silicide. For example, the gate electrode may include doped polysilicon, i.e. gate polysilicon. It can be understood by those skilled in the art that in some examples a gate electrode and the corresponding word line may be a continuous conductive structure. That is, the gate electrode may be considered to form a part of the word line of the gate layer 308, or the word line may be considered as a extension from the gate electrode to be coupled to peripheral circuits.

The source and the drain may be separated from each other by the gate layer 308 in the first direction (the z direction). That is, the gate layer 308 is formed between the source and the drain. Here, one of the source and the drain is disposed opposite to the substrate, so that the semiconductor body 302 is exposed when the substrate is removed, and the source, the drain and the corresponding connected bit line 100 are formed by doping the corresponding exposed end of the semiconductor body.

In some implementations, the transistor may be a vertical transistor, which as a substitute for a planar transistor serves as a switching and selecting device in the memory cell array of a DRAM or another memory device, and as a transistor with a vertical configuration it may have a reduced area and can simplify the layout of interconnection structures.

The memory cell array having vertical transistors and the periphery circuits for the memory cell array may be formed on different wafers and bonded face to face. Compared to the side-by-side configuration, the stacked memory cell array and peripheral circuits may further reduce the chip size and can improve array efficiency in combination with arrangement of planar capacitors.

In some implementations, due to the transistors with a vertical configuration, bit lines and word lines are disposed proximate to the bonding interface and the transistors with a vertical configuration may be coupled to peripheral circuits through a great number of (e.g., millions of) parallel bonding contacts, so that direct electrical connection of a short distance (e.g., in the order of magnitude of micron) between the memory cell array and the periphery circuits can be made to improve the throughput and the input/output (I/O) speed of the memory device.

Referring to FIG. 5, a plurality of transistors 30 form a transistor array, each transistor is connected to a bit line 100 and a word line 90 respectively, one of the source and the drain of each transistor 30 is connected to a second connection structure, the other of the source and the drain of each transistor 30 is connected to a bit line 100, the gate of each transistor 30 is connected to a word line 90, and the first connection structure 402 leads out as a common electrode 1202. In some implementations, as shown in FIG. 4, the semiconductor device further includes: a metal layer 110 disposed on the other side of the stacked structure 20 away from the transistors 30; and a second semiconductor structure 120 hybrid bonded with the first semiconductor structure 10 via the metal layer 110.

The metal layer may serve as the bonding interface for the bonding with the second semiconductor structure. The bonding interface may be a layer of a certain thickness including the top surface of the bonding layer of the second semiconductor structure and the bottom surface of the bonding layer of the first semiconductor structure.

It can be understood that the bonding interface is formed between the second semiconductor structure 120 and the first semiconductor structure 10 in a 3D memory device that are vertically bonded through bonding (e.g., hybrid bonding). Hybrid bonding (also referred to as “metal/dielectric hybrid bonding”) is a direct bonding technology (e.g., bonding is formed between surfaces without an intermediate layer (e.g., solder or adhesive)), and metal-metal (e.g., copper-copper) bonding and dielectric-dielectric (e.g., silicon oxide-silicon oxide) bonding may be obtained simultaneously. Data transfer between the memory cell array in the first semiconductor structure and the peripheral circuits in the second semiconductor structure may be performed via interconnection (e.g., the bonding contacts) through the bonding interface.

Hybrid bonding (also referred to as “metal/dielectric hybrid bonding”) is a direct bonding technology (e.g., bonding is formed between surfaces without an intermediate layer (e.g., solder or adhesive)), and metal-metal (e.g., copper-copper) bonding and dielectric-dielectric (e.g., silicon oxide-silicon oxide) bonding may be obtained simultaneously. Data transfer between the memory cell array in the first semiconductor structure 10 and the peripheral circuits in the second semiconductor structure 120 may be performed via interconnection (e.g., the bonding contacts) through the bonding interface, i.e. the metal layer 110.

The second semiconductor structure 120 includes peripheral circuits configured to control and sense the memory array devices on the memory array chip. The peripheral circuits may be any suitable digital, analog, and/or mixed-signal control and sensing circuits, including, but not limited to, page buffers, decoders (e.g., row decoders and column decoders), sense amplifiers, drivers (e.g., word line drivers), charge pumps, current or voltage references, or any active or passive components of a circuit (e.g., transistors, diodes, resistors or capacitors) that are configured to facilitate operations of a 3D memory device. In some implementations, peripheral circuits may include transistors as high-speed devices formed using an advanced logic process, for example, a 90 nm, 65 nm, 45 nm, 32 nm, 28 nm, 20 nm, 16 nm, 14 nm, 10 nm, 7 nm, 5 nm, 3 nm, 2 nm or another technology node.

In some implementations, as shown in FIG. 4, the second semiconductor structure 120 includes complementary metal oxide semiconductor (CMOS) 1204 and various types of peripheral circuits formed based on a CMOS technology, which can be implemented using a logic process (e.g., 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.) The peripheral circuits may be coupled to the first semiconductor structure 10 through bit lines, word lines, the common electrode of planar capacitors and any other suitable metal wiring. It is to be noted that the one or more peripheral circuits may include any suitable circuits that facilitate operations of the disclosed memory device by applying and sensing at least one of voltage signals or current signals to and from each memory cell through a word line and a bit line.

Peripheral circuits (also referred to as control and sensing circuits) may include any suitable digital, analog and/or mixed signal circuits that facilitate operations of the memory cell array. For example, the peripheral circuits may include one or more of page buffers, decoders (e.g., a row decoder and a column decoder), a sense amplifier, a driver (e.g., a word line driver), an input/output (I/O) circuit, a charge pump, a voltage source or generator, a current or voltage reference, any part of the above-mentioned function circuit (e.g., a sub-circuit) or any active or passive components of a circuit (e.g., transistors, diodes, resistors or capacitors).

Furthermore, it can be understood by those skilled in the art that in some implementations, the semiconductor device may further include any other circuits compatible with advanced logic processes including logic circuits (e.g., processors and programmable logic devices (PLD)) or memory circuits (e.g., static random access memories (SRAM)).

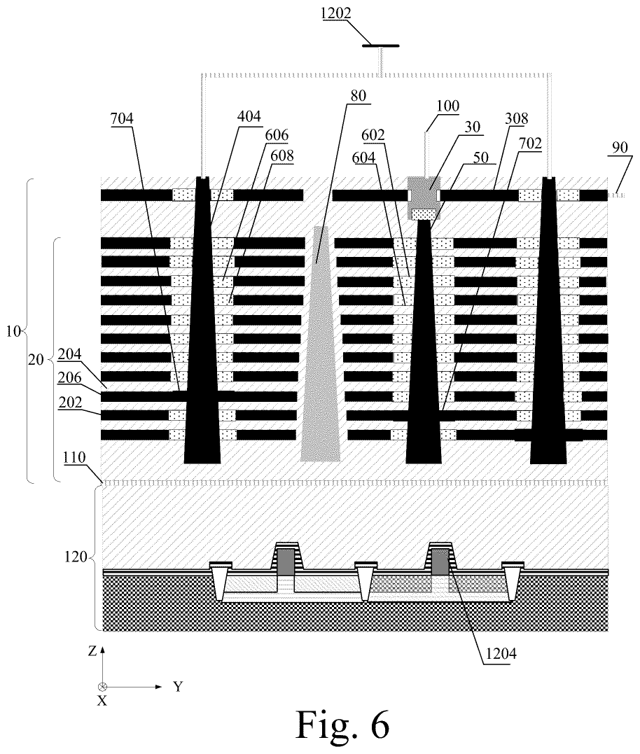

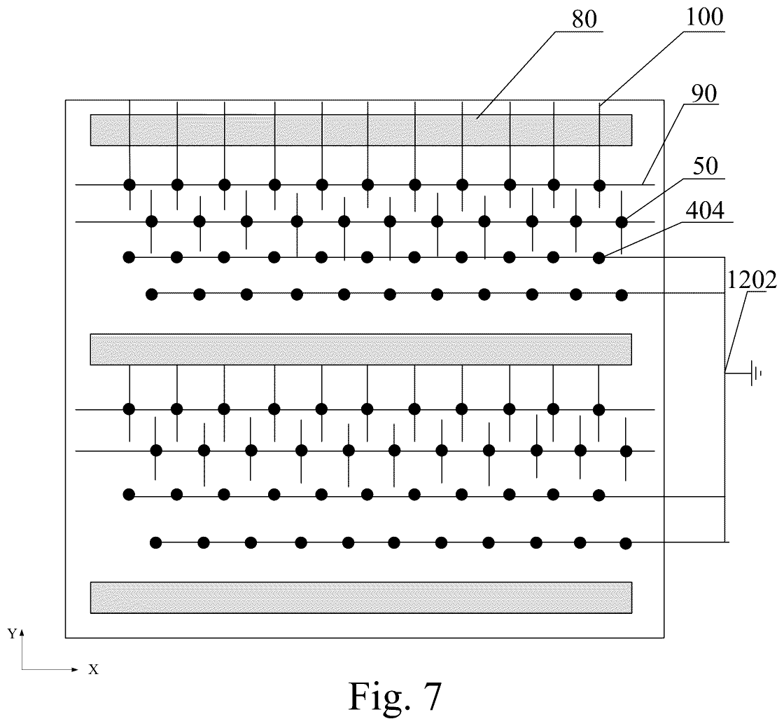

FIG. 6 shows a schematic side view cross-sectional diagram of a semiconductor device according to another implementation of the present disclosure and FIG. 7 shows a schematic planar cross-sectional diagram of the semiconductor device shown in FIG. 6.

As shown in FIG. 6, the semiconductor device includes a first semiconductor structure 10 including a stack structure 20 and a transistor 30. The stack structure includes first conductive layers 202 and second conductive layers 204 alternately stacked in the first direction, and the transistor 30 is disposed on one side of the stack structure 20 and connected with one of the first conductive layers 202.

In the stack structure 20, a first conductive layer 202 (also referred to as a first electrode plate) and a second conductive layer 204 (also referred to as a second electrode plate) adjacent to the first conductive layer 202 form a planar capacitor arranged in stacked planar layers. The stack structure 20 forms a plurality of planar capacitors, each of which has its first electrode plate connected to a transistor, so that a memory cell structure is formed to include a plurality of capacitors and a plurality of transistors. The fabrication process of forming two conductive layers stacked alternately in one direction is simple and easy.

In some implementations, the first conductive layers and the second conductive layers may be formed by forming sacrificial layers first when an original stack structure is formed and then replacing the sacrificial layers.

In some implementations, each first conductive layer and each second conductive layer have the same nominal thickness between about 25 nm and about 40 nm, for example, the same thickness between 25 nm and 40 nm, such as 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, any range bounded by any one of the values as a lower limit or any range bounded by any two of the values.

In some implementations, a first conductive layer and a second conductive layer may each include a plurality of conductive layers, for example, a W layer on a TiN layer. In some implementations, the first conductive layers and the second conductive layers may include the same conductive material. In some other implementations, the first conductive layers may include a first conductive material and the second conductive layers may include a second conductive material different from the first conductive material.

In some implementations, as shown in FIG. 6, the stack structure 20 further includes: a dielectric layer 206 between a first conductive layer 202 and a second conductive layer 204.

In some implementations, the dielectric layer may be formed directly when the original stack structure is formed.

In some implementations, the dielectric layer may include a dielectric material including, but not limited to, silicon oxide, silicon nitride, silicon oxynitride or any combination thereof.

In some implementations, each dielectric layer has a same nominal thickness between about 15 nm and about 30 nm, for example, a same thickness between 15 nm and 30 nm, such as 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, any range bounded by any one of the values as a lower limit or any range bounded by any two of the values.

In some implementations, as shown in FIG. 6, the stack structure 20 includes alternating conductive layers and dielectric layers, wherein a conductive layer is the first conductive layer 202 when it, as a first electrode plate, is connected to a transistor, and a conductive layer is a second conductive layer 204 when it, as a second electrode plate, is connected to a common electrode, and two conductive layers have a dielectric layer 206 therebetween. As shown in FIG. 6, one end of the whole stack structure adheres to a metal layer 110, and the other end is proximate to the transistor 30 and disposed opposite to the gate layer 308 of the transistor 30.

In this implementation, a first conductive layer and a second conductive layer act as electrode plates respectively, a dielectric layer and a first conductive layer and a second conductive layer on opposite sides of the dielectric layer constitute a planar capacitor configured to store charges or data. A first connection structure extends through the whole stack structure vertically. A first conductive layer is one side of a planar capacitor, which, via the other side, is connected to the first connection structure as a common electrode. A first conductive layer as the other side of a planar capacitor is configured for connection with a transistor. The capacity of capacitors in a memory cell can be adjusted by adjusting the number of the conductive layers joining a transistor. It facilitates improvement of the memory density when adjusting the number of the conductive layers joining a transistor.

In some implementations, as shown in FIG. 6, the first semiconductor structure 10 further includes another type of first connection structure 404, which extends through the stack structure 20 in the first direction, is connected with second conductive layers 204 and serves as a common electrode connected with the second electrode plates of the planar capacitors. The lead-out common electrode may not occupy the effective area of the first conductive layers and the second conductive layers, so that the planar capacitors can each have a relatively large capacity. Moreover, the fabrication process may be simplified by connecting the common electrode with a plurality of second conductive layers.

In some implementations, a plurality of sets of the first connection structures are included, the stack structure 20 includes a plurality of second conductive layers 204 and each of the second conductive layers 204 is connected to one set of the first connection structures 404.

In some implementations, a plurality of sets of the first connection structures are arranged side by side in the second direction perpendicular to the first direction. The first connection structure may be a pillar structure or a plate-like structure.

In some implementations, as shown in FIG. 6, a plurality of first connection structures 402 lead out from the stack structure to be connected to the common electrode 1202.

Here, there may be a plurality of sets of the first connection structures arranged side by side in the second direction, i.e. the x direction. The first connection structures and the second connection structures are disposed alternately in the third direction, i.e. the y direction. As shown in FIG. 7, the first connection structures 404 and the second connection structures 50 are disposed alternately in the y direction. Here, sets of the first connection structures and sets of second connection structures may be arranged alternately along the y axis with the alternating unit being one set or multiple sets.

In some implementations, as shown in FIG. 6, the first semiconductor structure 10 further includes: a second connection structure 50 that extends through the stack structure 20 in the first direction and is connected to the first conductive layers 202 and a transistor 30 respectively.

In some implementations, the second connection structure may include any suitable conductive material such as polysilicon, metal (e.g., tungsten (W), copper (Cu), aluminum (Al) or the like), a metal compound (e.g., titanium nitride (TiN), tantalum nitride (TaN) or the like) or silicide. In some implementations, each of a first connection structure 404 and a second connection structure 50 may both have a pillar structure.

In some implementations, a first connection structure 404, a second conductive layer 204, a first conductive layer 202 and a second connection structure 50 have a connection relationship with one-to-one correspondence.

In some implementations, a plurality of first connection structures and a plurality of second connection structures are formed synchronously and have the same structure and material and, when the stack structure has multiple second conductive layers, one of the second conductive layers is connected to one sets of the first connection structures correspondingly.

In some implementations, in order to form a second connection structure, a first connection hole may be formed first and includes a first sub-hole and a second sub-hole based on different fabrication processes. The first sub-hole may be formed in a prior process and then the second sub-hole may be formed along the first sub-hole in the post process. In order to form a first connection structure, a second connection hole is formed at the same time as the first connection hole and includes a third sub-hole and a fourth sub-hole based on different fabrication processes. The first and third sub-holes may be formed in a prior process and then the second and fourth sub-holes may be formed along the first sub-hole in the post process. In some implementations, as shown in FIG. 6, a first communication component 702 is disposed between a second connection structure 50 and one of the first conductive layers 202 connected to each other.

In some implementations, as shown in FIG. 6, a second communication component 704 is disposed between a first connection structure 404 and one of the second conductive layers 204 connected to each other. First communication components 702 and second communication components 704 are arranged alternately in the first direction.

In some implementations, the first communication component 702, the second communication component 704, the first connection structure 404, the second connection structure 50, the first conductive layer 202 and the second conductive layer 204 may include the same conductive material including but not limited to, W, Co, Cu, Al, polysilicon, doped silicon, silicide or any combination thereof.

In some implementations, the first communication component is formed in a fabrication process between the process for the first sub-hole and the process for the second sub-hole, and the second communication component is formed in a fabrication process between the process for the third sub-hole and the process for the fourth sub-hole.

As shown in FIG. 6, the transistor 30 is connected to the first electrode plate (i.e. a first conductive layer 202) of a planar capacitor through a second connection structure 50 and a first communication component 702, and the second electrode plate (i.e. the second conductive layer 204) of the planar capacitor is connected to the common electrode 1202 through a second communication component 704 and a first connection structure 404, forming a memory cell in an array structure based on transistors correspondingly. The memory cell is connected to a word line 90 through the gate layer 308 of a transistor 30.

As shown in FIG. 7, first connection structures 404 and second connection structures 50 are arranged alternately, each second connection structure 50 is connected to a transistor correspondingly (not shown in the figure) and connected to a word line 90 and a bit line 100 through the transistor, and a plurality of first connection structures 404 are all connected to a common electrode 1202.

In some implementations, in a stack structure having a plurality of sets of first conductive layers, dielectric layers and second conductive layers, one second connection structure or one set of connection structures is connected only to one of the first conductive layers. Therefore, with respect to one second connection structure or one set of second connection structures and for a first conductive layer with a connection relationship therewith, a first communication component needs to be formed at periphery in the horizontal direction and connected to the first conductive layer, while for the first conductive layers and the second conductive layers without any connection relationship therewith, insulating components need to be formed at periphery. As shown in FIG. 6, an insulating component disposed between a second connection structure 50 and a second conductive layer 204 is designated as a first isolation layer 602, and an insulating component disposed between a second connection structure 50 and one of the first conductive layers 202 isolated from each other is designated as a second isolation layer 604.

In some implementations, for the first isolation layer and the second isolation layer, oxide (OX) material may be used as the insulating material, may be generated using atomic layer deposition (ALD) and may be aluminum oxide (Al₂O₃). In the stack structure, the first isolation layer and the second isolation layer are formed respectively by depositing ALD OX to isolate the second connection structure from the second conductive layers and the first conductive layers without connection relationship therewith.

In some implementations, as shown in FIG. 6, the stack structure 20 further includes a third isolation layer 606 disposed between the first connection structure 404 and a first conductive layer 202 to isolate the connection structure 404 from the first conductive layer 202.

In some implementations, as shown in FIG. 6, the stack structure 20 further includes a fourth isolation layer 608 disposed between a first connection structure 404 and one of the second conductive layers 204 isolated from each other.

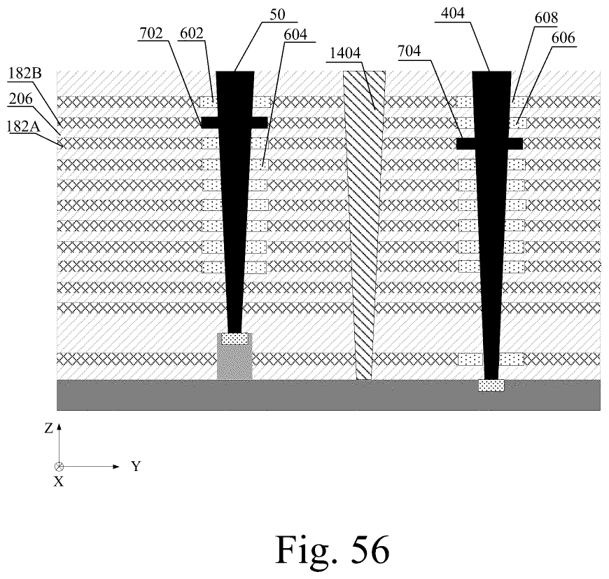

As shown in FIG. 56, the fourth isolation layer 608 is configured to isolate the first connection structure 404 and the second conductive layers 204, which are not in communication, from each other.

In some implementations, the third isolation layer and the fourth isolation layer may be formed from atomic layer deposition (ALD) oxide (OX) material as an insulating material. The OX may be aluminum oxide (Al₂O₃). In the stack structure, the third isolation layer may be formed by depositing ALD OX to isolate the first connection structure from the first conductive layer and the fourth isolation layer may be formed by depositing ALD OX to isolate the first connection structure and the one of the second conductive layers, which have no connection relationship therebetween, from each other.

In some implementations, the first semiconductor structure 10 further includes an isolation structure 80 extending through the stack structure 20 in the first direction (as shown in FIG. 6) and extending along the third direction perpendicular to the first direction (as shown in FIG. 7). It can be understood by those skilled in the art that the isolation structure 80 serves to separate the stack structure into memory blocks.

In some implementations, the transistors 30 may be vertical metal-oxide-semiconductor field effect transistors (MOSFET).

In some implementations, as shown in FIG. 6, the semiconductor device further includes: a metal layer 110 disposed on the other side of the stacked structure 20 away from the transistors 30; and a second semiconductor structure 120 hybrid bonded with the first semiconductor structure 10 via the metal layer 110.

The metal layer may serve as the bonding interface for the bonding with the second semiconductor structure. The bonding interface may be a layer of a certain thickness including the top surface of the bonding layer of the second semiconductor structure and the bottom surface of the bonding layer of the first semiconductor structure.

It can be understood that the bonding interface is formed between the second semiconductor structure 120 and the first semiconductor structure 10 in a 3D memory device that are vertically bonded through bonding (e.g., hybrid bonding). Hybrid bonding (also referred to as “metal/dielectric hybrid bonding”) is a direct bonding technology (e.g., bonding is formed between surfaces without an intermediate layer (e.g., solder or adhesive)), and metal-metal (e.g., copper-copper) bonding and dielectric-dielectric (e.g., silicon oxide-silicon oxide) bonding may be obtained simultaneously. Data transfer between the memory cell array in the first semiconductor structure and the peripheral circuits in the second semiconductor structure may be performed via interconnection (e.g., the bonding contacts) through the bonding interface.

Hybrid bonding (also referred to as “metal/dielectric hybrid bonding”) is a direct bonding technology (e.g., bonding is formed between surfaces without an intermediate layer (e.g., solder or adhesive)), and metal-metal (e.g., copper-copper) bonding and dielectric-dielectric (e.g., silicon oxide-silicon oxide) bonding may be obtained simultaneously. Data transfer between the memory cell array in the first semiconductor structure 10 and the peripheral circuits in the second semiconductor structure 120 may be performed via interconnection (e.g., the bonding contacts) through the bonding interface 110.

The second semiconductor structure 120 includes peripheral circuits configured to control and sense the memory array devices on the memory array chip. The peripheral circuits may be any suitable digital, analog, and/or mixed-signal control and sensing circuits, including, but not limited to, page buffers, decoders (e.g., row decoders and column decoders), sense amplifiers, drivers (e.g., word line drivers), charge pumps, current or voltage references, or any active or passive components of a circuit (e.g., transistors, diodes, resistors or capacitors) that are configured to facilitate operations of a 3D memory device. In some implementations, peripheral circuits may include transistors as high-speed devices formed using an advanced logic process, for example, a 90 nm, 65 nm, 45 nm, 32 nm, 28 nm, 20 nm, 16 nm, 14 nm, 10 nm, 7 nm, 5 nm, 3 nm, 2 nm or another technology node.

In some implementations, as shown in FIG. 6, the second semiconductor structure 120 includes complementary metal oxide semiconductor (CMOS) 1204 and various types of peripheral circuits formed based on a CMOS technology, which can be implemented using a logic process (e.g., 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.) The peripheral circuits may be coupled to the first semiconductor structure 10 through bit lines, word lines, the common electrode of planar capacitors and any other suitable metal wiring. It is to be noted that the one or more peripheral circuits may include any suitable circuits that facilitate operations of the disclosed memory device by applying and sensing at least one of voltage signals or current signals to and from each memory cell through a word line and a bit line.

Peripheral circuits (also referred to as control and sensing circuits) may include any suitable digital, analog and/or mixed signal circuits that facilitate operations of the memory cell array. For example, the peripheral circuits may include one or more of page buffers, decoders (e.g., a row decoder and a column decoder), a sense amplifier, a driver (e.g., a word line driver), an input/output (I/O) circuit, a charge pump, a voltage source or generator, a current or voltage reference, any part of the above-mentioned circuit (e.g., a sub-circuit) or any active or passive components of a circuit (e.g., transistors, diodes, resistors or capacitors).

Furthermore, it can be understood by those skilled in the art that in some implementations, the semiconductor device may further include any other circuits compatible with advanced logic processes including logic circuits (e.g., processors and programmable logic devices (PLD)) or memory circuits (e.g., static random access memories (SRAM)).

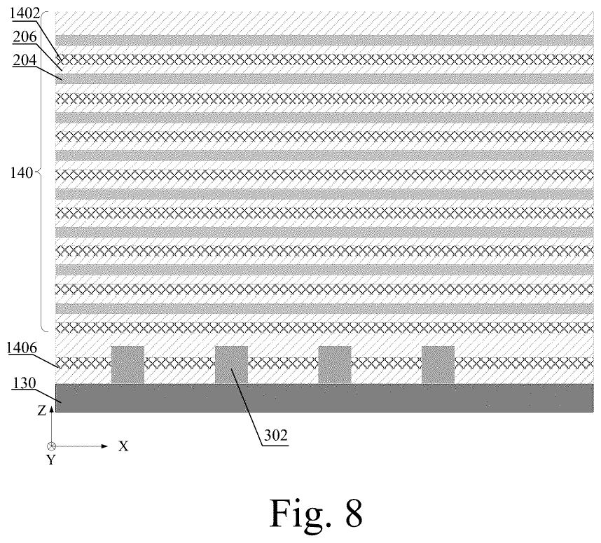

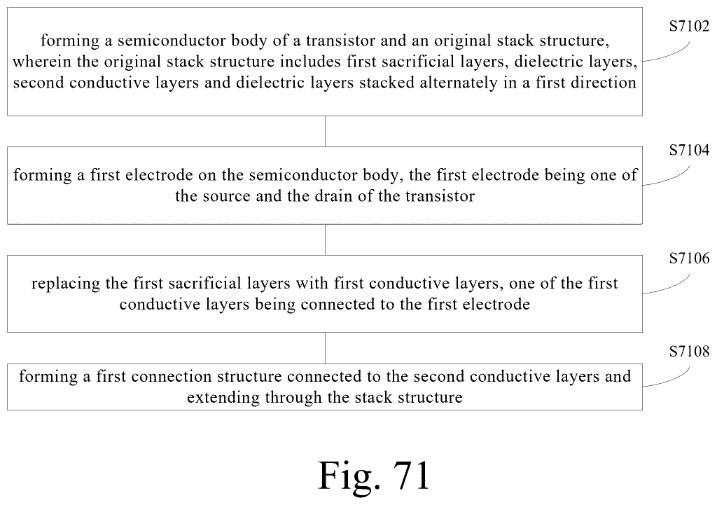

FIGS. 8 to 31 show a fabrication process of a semiconductor device according to various implementations of the present disclosure. FIG. 71 shows a flow chart of a method of forming a semiconductor device according to some implementations of the present disclosure. The semiconductor device shown in FIGS. 8 to 31 and FIG. 71 includes the semiconductor device shown in FIGS. 4 and 5.

Referring to FIG. 71, a process of forming a first semiconductor structure in the method of forming a semiconductor device is provided, the process including the following operations.

In operation S7102, a semiconductor body of a transistor and an original stack structure are formed and the original stack structure includes first sacrificial layers, dielectric layers, second conductive layers and dielectric layers stacked alternately in the first direction.

In some implementations as shown in FIG. 8, a semiconductor body 302 and an original stack structure 140 are formed on a substrate 130, the original stack structure 140 includes first sacrificial layers 1402, dielectric layers 206, second conductive layers 204 and dielectric layers 206 stacked alternately in the first direction, and the substrate 130 may include silicon (e.g., single crystal silicon, c-Si), silicon germanium (SiGe), gallium arsenide (GaAs), germanium (Ge), silicon on insulator (SOI) or any other suitable material.

In some implementations as shown in FIG. 8, in the process of forming the semiconductor body 302, a third sacrificial layer 1406 parallel to the original stack structure 140 is further formed.

In some implementations, when the original stack structure is taken as a whole, one end of the original stack structure is the upper surface, the other end of the original stack structure is close to the semiconductor body 302 and disposed parallel to the third sacrificial layer 1406 relatively, and dielectric is filled between the original stack structure and the third sacrificial layer 1406.

In some implementations, the first sacrificial layers 1402, the dielectric layers 206, the second conductive layers 204 and the dielectric layers 206 may be formed alternately using a variety of thin film deposition processes such as CVD, PVD, ALD and the like. The second conductive layers 204 may include any suitable conductive material, such as metal (e.g., W, Cu, Al or the like) or a metal compound (e.g., TiN, TaN or the like), and the dielectric layer 206 may include a dielectric material including, but not limited to, silicon oxide, silicon nitride, silicon oxynitride or any combination thereof. The first sacrificial layers 1402 may be insulating layers including any suitable insulating material that has an etching rate different from those of materials of the dielectric layers 206 and the second conductive layers 204 during one or more selective etching processes. In some implementations, the first sacrificial layers 1402 include silicon nitride.

In some implementations as shown in FIG. 8, the semiconductor body 302 may extend above the top surface of the substrate 130 and, as described with respect to a fabrication process, the semiconductor body 302 may be formed from the substrate (e.g., by etching or epitaxy) and thus have the same semiconductor material (e.g., crystalline silicon) as the substrate (e.g., a silicon substrate). In some implementations, in order to form the semiconductor body, an opening extending through a stack of dielectric layers is formed by etching to expose a part of the substrate and the semiconductor body grows epitaxially from the exposed part of the substrate in the opening. The process of fabricating the semiconductor body 302 through epitaxial growth may include, but not limited to, vapor-phase epitaxy (VPE), liquid-phase epitaxy (LPE), molecular-beam cpitaxy (MPE) or any combination thereof. Epitaxy may be performed upward (toward the positive z direction) from the exposed part of the substrate 130 in the opening. The semiconductor body 302 may have the same shape as the opening, such as a cube shape or a cylinder shape dependent on the shape of the opening.

Referring back to FIG. 71, the method further includes operation S7104, in which a first electrode is formed on the semiconductor body to act as one of the source and the drain of a transistor. After replacing the first sacrificial layers with the first conductive layers, the first electrode is coupled to a first conductive layer.

In some implementations, forming a first electrode on the semiconductor body further includes: forming a connection hole extending through the stack structure to the semiconductor body in the first direction.

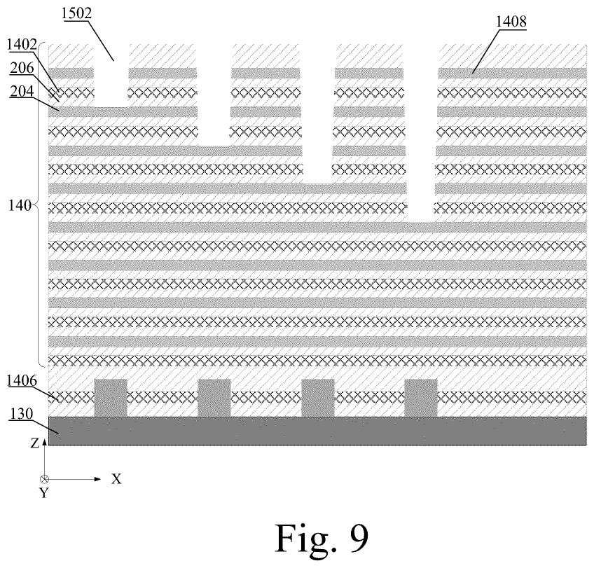

In some implementations as shown in FIG. 9, the side of the stack structure away from the third sacrificial layer 1406 is a first layer 1408, while the side of the stack structure proximate to the third sacrificial layer 1406 is a second layer 1410; forming a connection hole extending through the stack structure to the semiconductor body in the first direction includes: forming a plurality of sets of the first sub-holes 1502 that extend through the first layer in the first direction and stop first on a different second conductive layer 204. In some implementations, a plurality of columns of first sub-holes 1502 are formed in the second direction (the x direction) and each column of first sub-holes 1502 are arranged in the third direction (the y direction) and stop at the same second conductive layer 204. In some implementations, as shown in FIG. 9, the second conductive layers 204, at which the first sub-holes stop, are at positions decreasing in height successively.

In some implementations, the upper surface, the first layer 1408 and the like of the original stack structure 140 are etched successively through patterning and etching using photolithography and an etching process to form first sub-holes 1502 in alignment with semiconductor bodies. In some implementations, photolithography is performed using an etch mask (e.g., a photoresist mask) to pattern openings for connections holes based on for example a design for word lines and bit lines, and one or more dry etching and/or wet etching processes (e.g., reactive ion etching (RIE)) are performed to etch through a first sacrificial layer 1402, a dielectric layer 206, a second conductive layer 204 and a dielectric layer 206 and stop at and expose the specified second conductive layer 204.

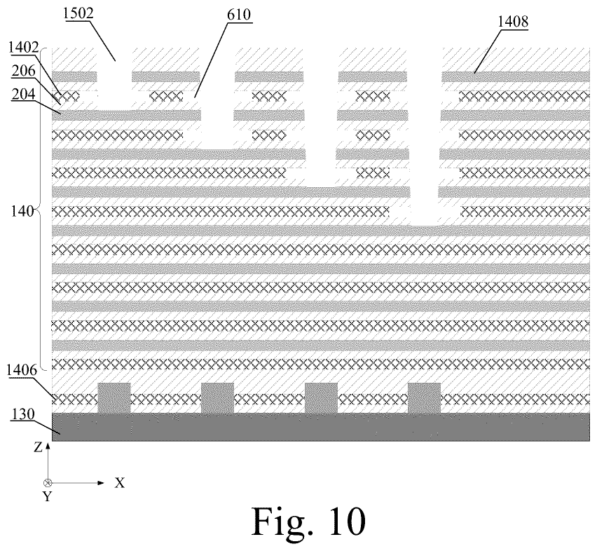

In some implementations as shown in FIG. 10, a first recess 610 is formed at the portion of the inner wall of the first sub-hole 1502 belonging to the first sacrificial layer 1402, and in some implementations the first sacrificial layer 1402 is etched off through the first sub-hole 1502. For example, wet etchant may be applied through the first sub-hole 1502 to etch the first sacrificial layer 1402 selectively by wet etching to form the first recess 610.

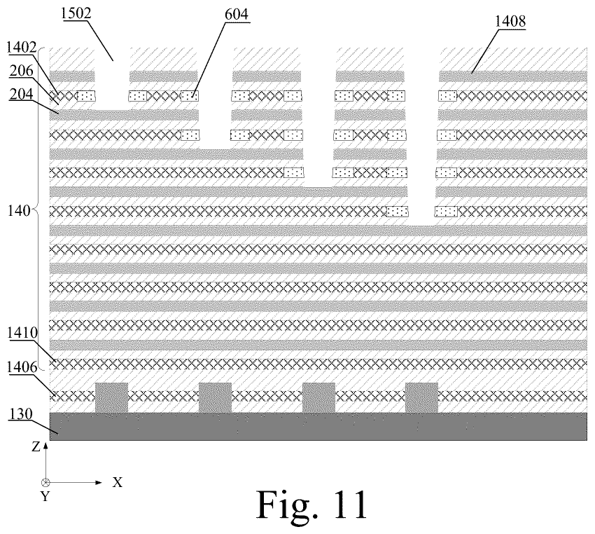

In some implementations as shown in FIG. 11, a second isolation layer 604 is deposited in the first recess 610 to isolate the structure in the hole from the first sacrificial layer 1402 and in turn isolate the structure in the hole from a first conductive layer 202 when the first sacrificial layer 1402 is replaced by the first conductive layer 202.

For example, the deposition process includes chemical vapor deposition (CVD), physical vapor deposition (PVD), atomic layer deposition (ALD) or the like.

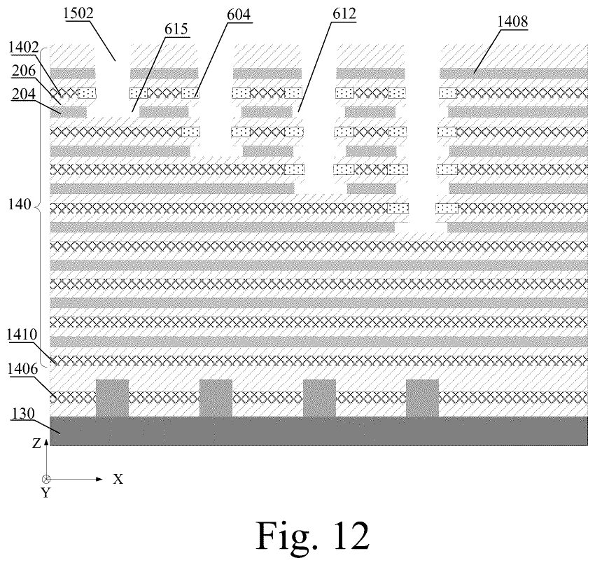

In some implementations as shown in FIG. 12, a second recess 612 is formed at the portion of the inner wall of the connection hole 150 belonging to the second conductive layer 204. A first bottom recess 616 is formed in each of the second conductive layers 204, at which a hole stops. In some implementations, the second conductive layer 204 is etched off through the first sub-hole 1502. For example, wet etchant is applied through the first sub-hole 1502 to etch the second conductive layer 204 selectively by wet etching.

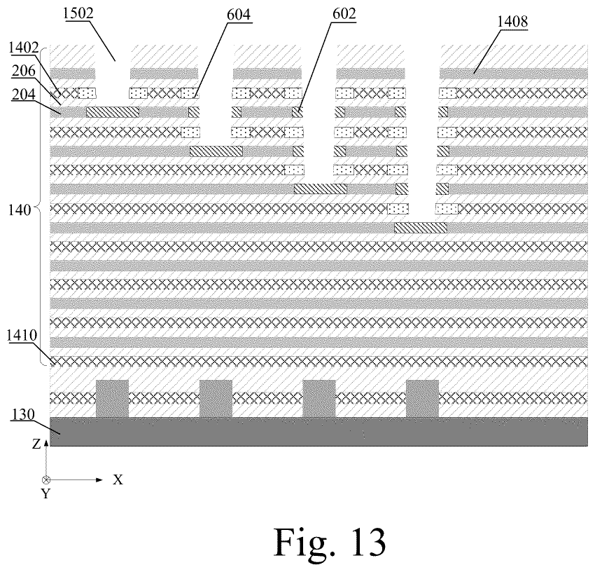

In some implementations as shown in FIG. 13, an insulating material is deposited in the first bottom recess 616 and the second recess 612 to deposit a first isolation layer 602 for isolation of the second conductive layer 204 with the second inner wall being located at the second conductive layer 204. In some implementations, an oxide (OX) material may be used as the insulating material, may formed using atomic layer deposition (ALD) and may be aluminum oxide (Al₂O₃).

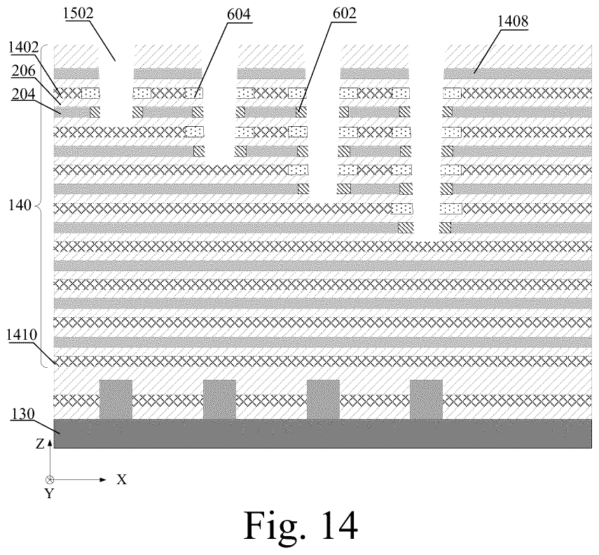

In some implementations as shown in FIG. 14, etching of the first sub-hole 1502 is continued with the first isolation layer 602 formed from the bottom recess 616 being taken as the upper surface, and the etching goes through the first isolation layer 602 and a dielectric layer 206 and stops at the next one of the first sacrificial layers 1402.

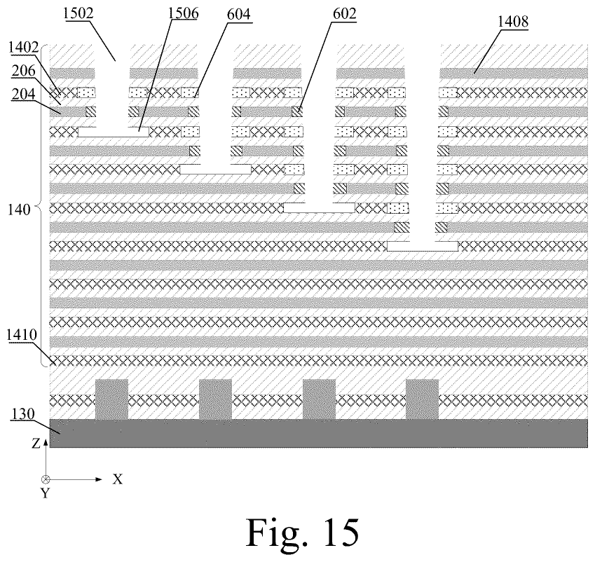

In some implementations as shown in FIG. 15, a recess 1506 is formed in each of the first sacrificial layers 1402 that forms the bottom of a first sub-hole 1502 as shown in FIG. 14.

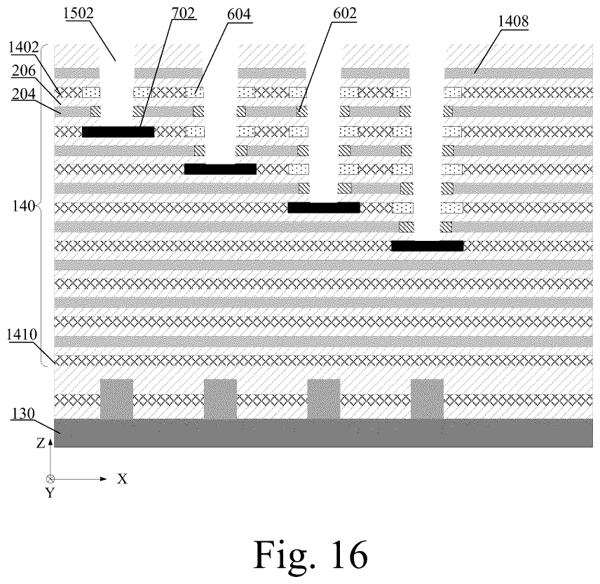

In some implementations as shown in FIG. 16, a conductive material is deposited in the recess 1506 at the bottom of the first sub-hole to form a first communication component 702 in contact with the first sacrificial layer, and for example the deposition of the conductive material may include depositing the conductive material through one or more thin film deposition processes, including, but not limited to, chemical vapor deposition (CVD), physical vapor deposition (PVD), atomic layer deposition (ALD), plating, electroless plating or any combination thereof.

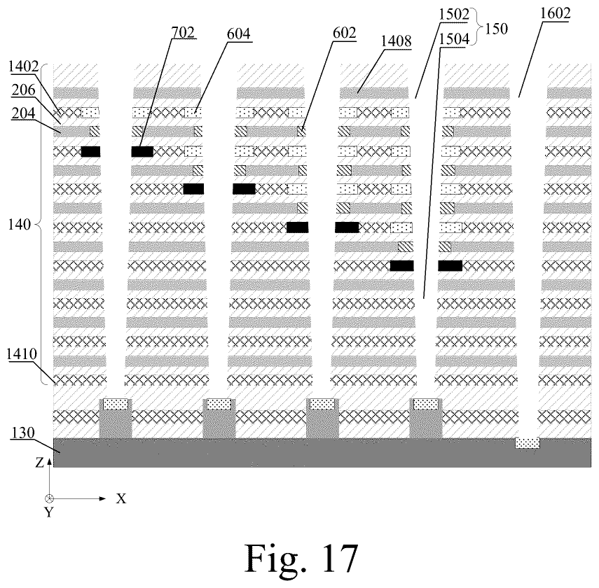

In some implementations as shown in FIG. 17, a second sub-hole 1504 is formed to extend through the first communication component 702 along the first direction and further through the second layer 1510. The first sub-hole 1502 and the second sub-hole 1504 are in communication with each other to form a connection hole 150.

In some implementations as shown in FIG. 17, forming a connection hole extending through the stack structure to the semiconductor body along the first direction with the second layer 1410 being located on the side near the semiconductor body further includes: forming an original slit 1602 that extends through the stack structure in the first direction and stops at the substrate 130. In some implementations, the original slit 1602 is patterned and etched using photolithography and an etching process.

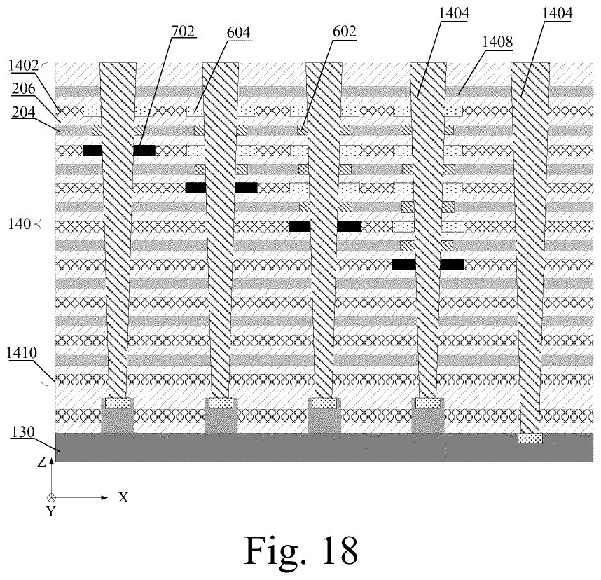

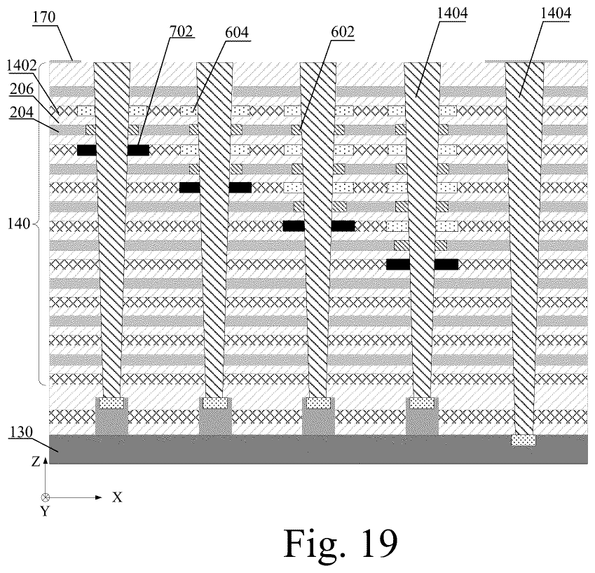

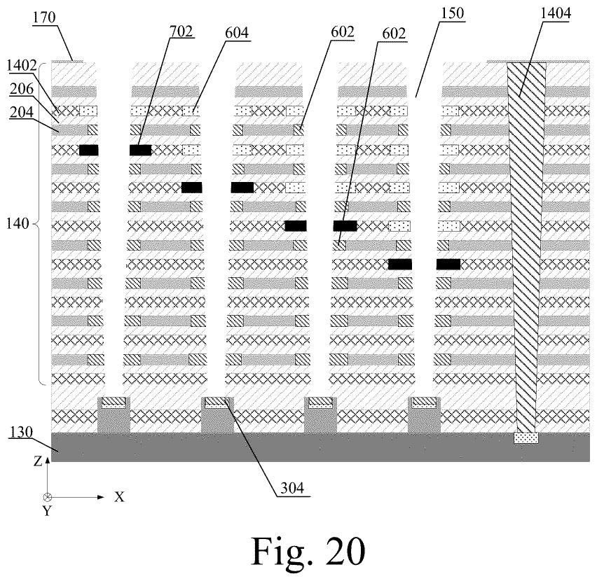

In some implementations as shown in FIG. 18, the method further includes: depositing a second sacrificial layer 1404 into the connection hole 150 and the original slit 1602. In some implementations, the second sacrificial layer 1404 may be formed using any suitable deposition process, such as CVD, PVD, ALD or the like, followed by a chemical mechanical polishing (CMP) process. As shown in FIG. 19, a protecting layer 170 is formed on the end of the original stack structure 140 away from the substrate 130. The protecting layer 170 is further etched to expose the ends of the connection hole 150 and the original slit 1602 filled with the second sacrificial layer 1404. In some implementations, a second connection structure is formed after removing the second sacrificial layer 1404 deposited in the connection hole. In some implementations as shown in FIG. 20, after removing the second sacrificial layer 1404 in the connection hole, at least one of an implantation process or a thermal diffusion process is performed through the connection hole 150 to dope P-type dopant or N-type dopant into the exposed upper end of the semiconductor body 302 and in turn form a source/drain, i.e. a first electrode 304. In some implementations, a silicide layer is formed on the first electrode 304 by performing a silicidation process on the exposed upper end of the semiconductor body 302.

In some implementations as shown in FIG. 20, deposition of first isolation layers 602 for isolation of second conductive layers 204 are continued in the connection hole 150 with the second inner wall being located at the second conductive layers 204. In some implementations, an oxide (OX) material may be used as the insulating material, may be formed using atomic layer deposition (ALD) and may be aluminum oxide (Al₂O₃).

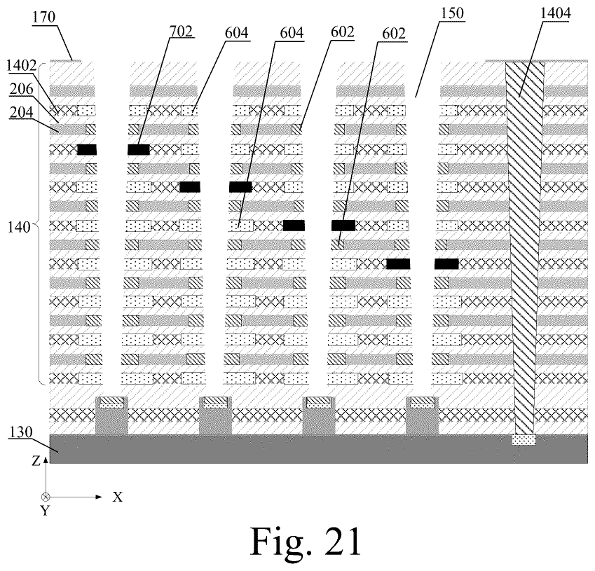

In some implementations as shown in FIG. 21, deposition of second isolation layers 604 are continued in the connection hole 150 to isolate the structure in the hole from the first sacrificial layers 1402 and in turn isolate the structure in the hole from first conductive layers 202 when the first sacrificial layers 1402 are replaced by the first conductive layers 202. For example, the deposition process includes chemical vapor deposition (CVD), physical vapor deposition (PVD), atomic layer deposition (ALD) or the like. The protecting layer 170 is removed after formation of the second isolation layers 604.

Referring back to FIG. 71, the method further includes operation S7106, in which first sacrificial layers are replaced by first conductive layers with one first conductive layer being connected to the first electrode.

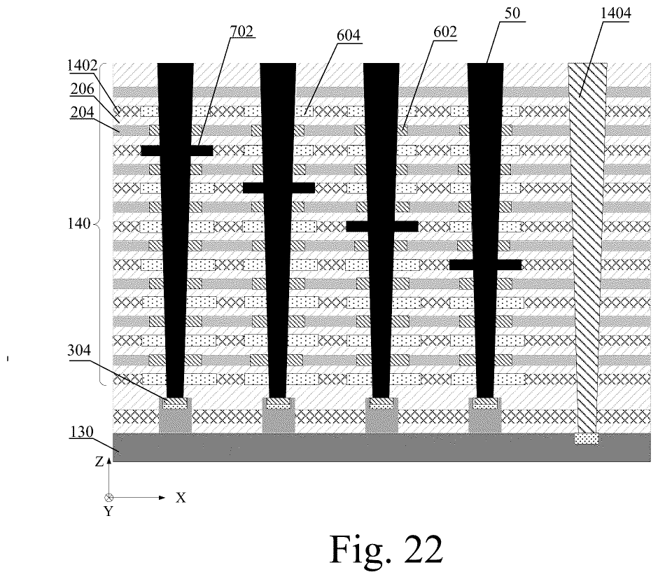

As shown in FIG. 22, before replacing the first sacrificial layers with first conductive layers, a second connection structure 50 is formed in the connection hole to be connected to one first sacrificial layer 1402 and the first electrode 304. The second connection structure 50 is connected to the first communication component 702 in the horizontal direction via the lateral sides so as to be connected to the first sacrificial layer 1402. The end of the second connection structure is connected to the first electrode 304 and in turn to the transistor. After replacing the first sacrificial layers 1402 with first conductive layers, electrical connection is further achieved between a first conductive layer in a planar capacitor and the transistor. In some implementations, a deposition process such as CVD, PVD, ALD or the like may be performed to deposit W in the connection hole 150. Then chemical mechanical polishing is done on the deposited W to form the second connection structure 50.

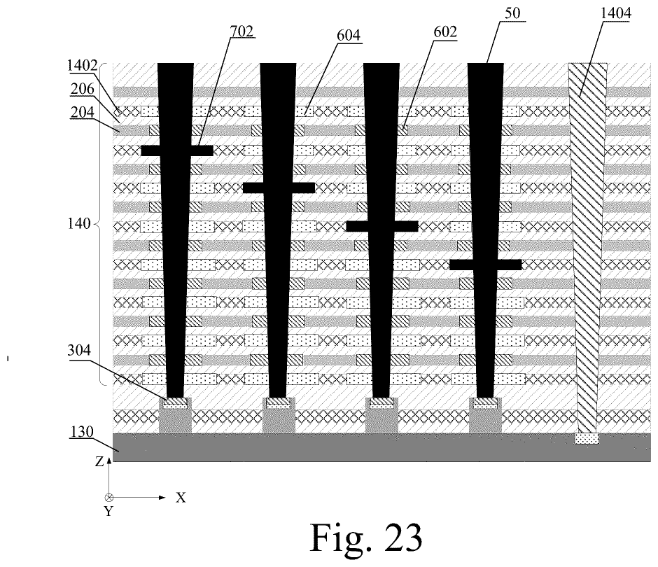

After forming the second connection structure 50, as shown in FIG. 23, the second sacrificial layer 1404 in the original slit 1602 is removed to expose the original slit 1602. The original slit 1602 is configured to form a first connection structure.

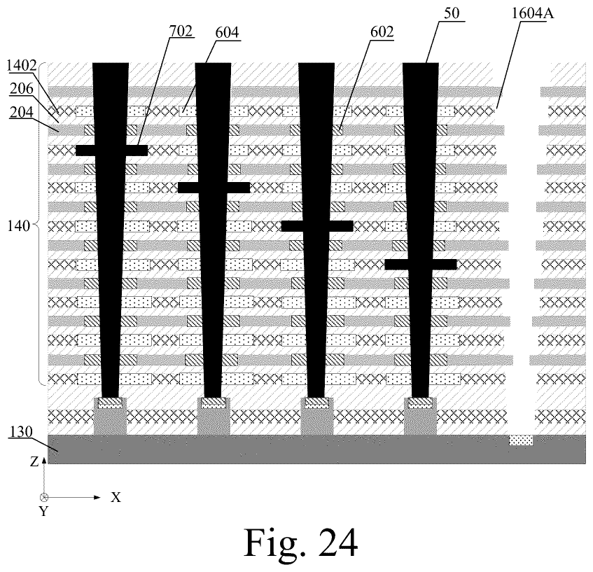

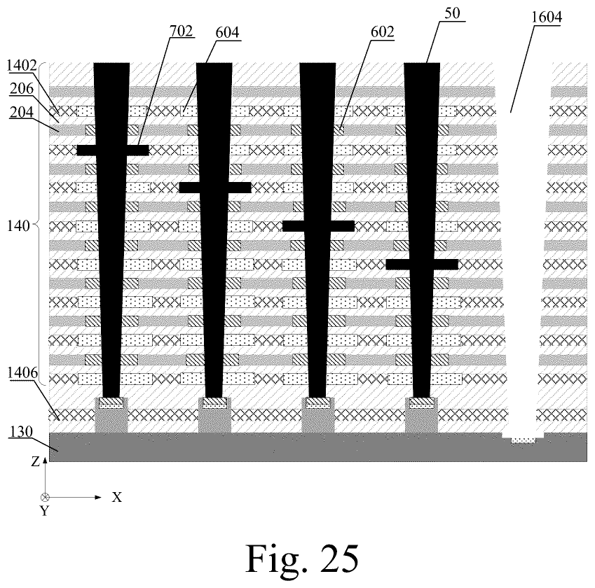

Before forming the first connection structure, the original slit 1602 needs to be expanded. Since the first sacrificial layers 1402 and the dielectric layers 206 may be insulating layers and the second conductive layers 204 are conductive layers, the hole expansion may be achieved by etching the insulating layers and the conductive layers respectively. As shown in FIG. 24, after etching of the insulating layers is finished, recesses 1604A are formed and, as shown in FIG. 25, after etching of the conductive layers is finished, an intermediate slit 1604 is formed to expose the first sacrificial layers 1402 and the third sacrificial layer 1406.

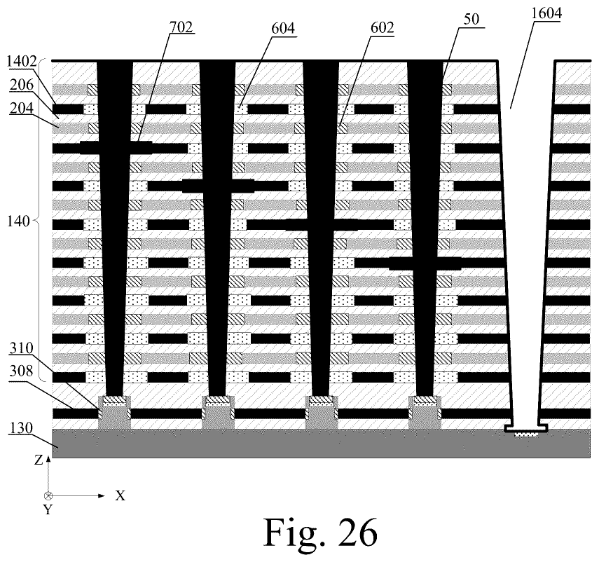

As shown in FIG. 26, the method further includes forming a gate dielectric layer 310. In some implementations, after removing the third sacrificial layer 1406, the sidewalls of the semiconductor body 302 are exposed and oxidized to form the gate dielectric layer 310. The gate dielectric layer 310 may join the corresponding semiconductor body 302 fully. In some implementations, at least one of a wet oxidization process or a dry oxidization process (e.g., ISSG) may be performed to form native oxide (e.g., silicon oxide) on the semiconductor body 302 (e.g., single crystal silicon) as the gate dielectric 310. In some implementations, a dielectric layer (e.g., silicon oxide) is deposited on the exposed portions of the semiconductor body 302 using one or more thin film deposition processes (including, but not limited to, CVD, PVD, ALD or any combination thereof) to form the gate dielectric layer 310.

There are exposed portions of the first sacrificial layers and the third sacrificial layer at the sidewalls of the intermediate slit 1604. The sacrificial layers are removed to form horizontal trenches (not shown in the figure). The first conductive layers 202 and the gate layer 308 are formed in the horizontal trenches through the exposed portions, as shown in FIG. 26.

Furthermore, after forming the first conductive layers 202, the original stack structure 140 is converted into the stack structure 20.

Referring back to FIG. 71, the method further includes operation S7108, in which a first connection structure is formed to be connected to a second conductive layers and extend through the stack structure.

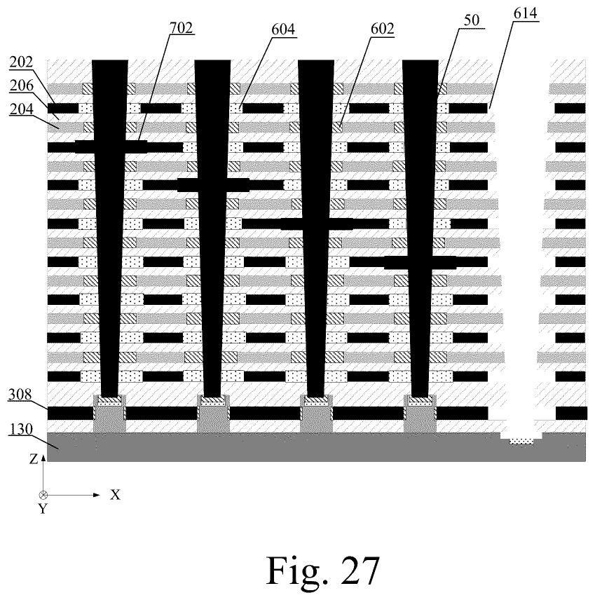

The first connection structure needs to be electrically connected to the second conductive layers as a common electrode and as a result the first connection structure needs to be electrically isolated from the first conductive layers and the gate layer. In order for the first connection structure to be electrically isolated from the first conductive layers and the gate layer, as shown in FIG. 27, the portions of the sidewalls of the intermediate slit 1604 at the first conductive layers 202 and the gate layer 308 are etched to form third recesses 614.

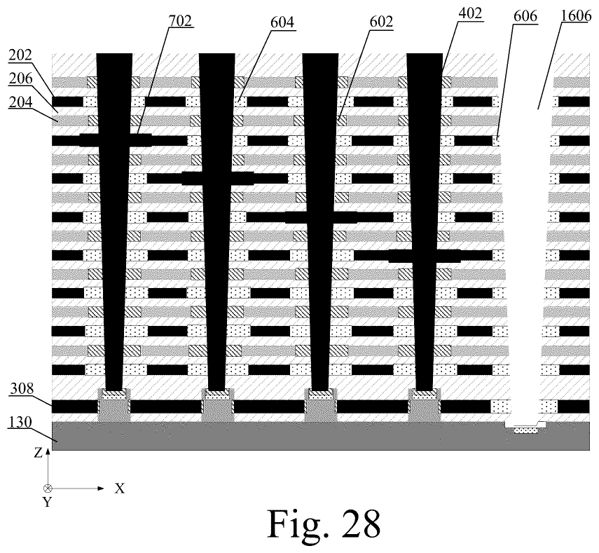

In some implementations as shown in FIG. 28, third isolation layers 606 are deposited in the third recesses 614 for isolation of the first conductive layers 202 and the gate layer 308 and a corresponding target slit 1606 is formed. In some implementations, a deposition process such as CVD, PVD, ALD or the like may be performed. In some implementations, the third isolation layers may be formed from atomic layer deposition (ALD) oxide (OX) material as an insulating material. The OX may be aluminum oxide (Al₂O₃).

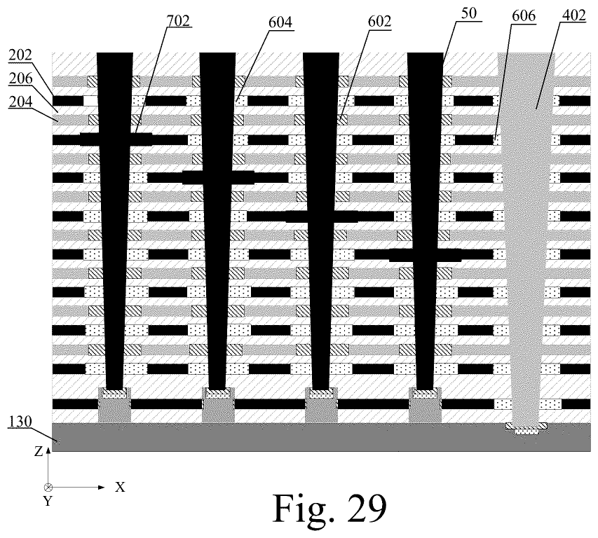

In some implementations as shown in FIG. 29, forming a first connection structure connected to the second conductive layers and extending through the stack structure includes: filling the target slit 1606 to form the first connection structure 402. In some implementations, the first connection structure 402 includes, but not limited to, W, Co, Cu, Al, polysilicon, doped silicon, silicide or any combination thereof. Or it can be POLY, conductive metal or a metal compound. For example, the conductive layers may be W layers or POLY layers.

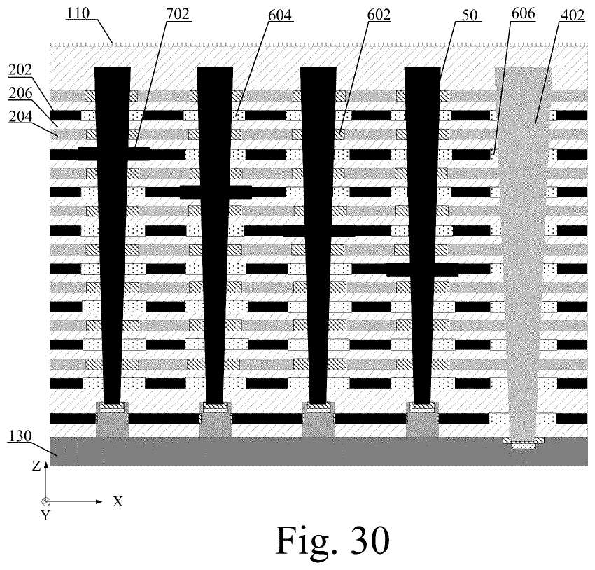

In some implementations as shown in FIG. 30, after forming the first connection structure 402, in order to cover the exposed surfaces of the first connection structure 402, and the second connection structure 50, in some implementations, a dielectric layer 206A may be formed through a plurality of thin film deposition processes such as CVD, PVD, ALD and the like to cover the exposed surfaces of the first connection structure 402, and the second connection structure 50.

Referring back to FIG. 30, the method further includes: depositing a metal layer 110 on the side of the stack structure 140 away from the transistors as a bonding interface. In some implementations, the metal layer 110 may serve as the bonding interface for the bonding with the second semiconductor structure. The bonding interface may be a layer of a certain thickness including the top surface of the bonding layer of the second semiconductor structure and the bottom surface of the bonding layer of the first semiconductor structure.

In some implementations, the method further includes: removing the substrate 130 on the side of the semiconductor body away from the stack structure to expose the semiconductor body using, for example, at least one of a planarization process or an etching process.

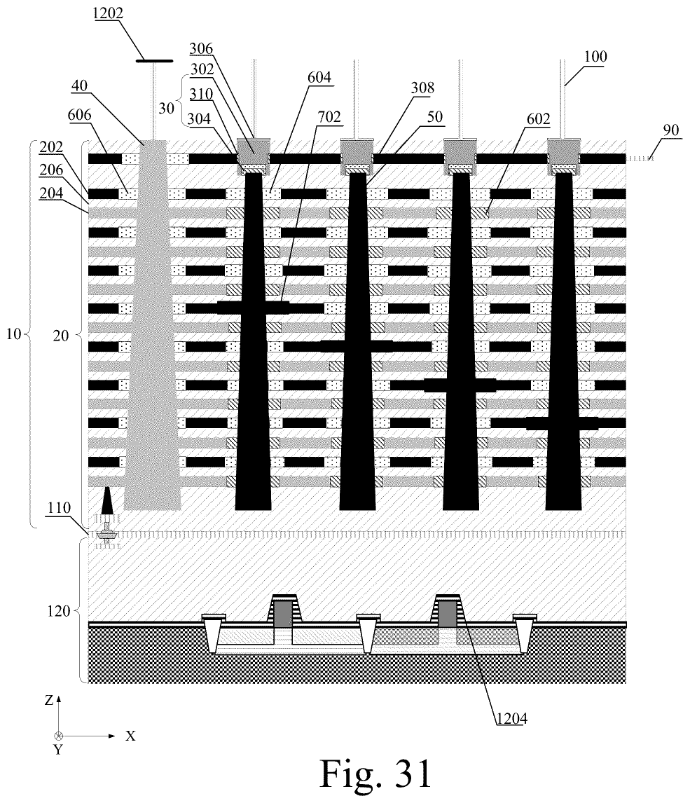

At the exposed end of the semiconductor body 302, a second electrode 306 is formed to be connected to a bit line 100 and serves as the other of the source and the drain of a transistor. As shown in FIG. 31, exposed upper end of each semiconductor body 302 (i.e. the one the two ends of the semiconductor body 302 in the vertical direction (the z direction) away from the carrier substrate 130) is doped to form the other source/drain, i.e. the second electrode 306. In some implementations, at least one of an implantation process or a thermal diffusion process is performed to dope P-type dopant or N-type dopant into the exposed upper end of the semiconductor body 302 and in turn form the second electrode 306. In some implementations, a silicide layer is formed on the second electrode 306 by performing a silicidation process on the exposed upper end of the semiconductor body 302. In some implementations, thereby a vertical transistor 30 including the semiconductor body 302, the source, the drain, the gate layer 308 and the gate dielectric 310 is formed. Here, the second electrode 306 is connected to a bit line 100 and the gate layer 308 is connected to a word line 90.

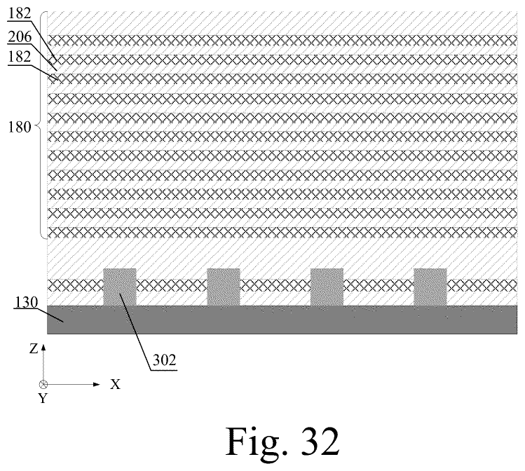

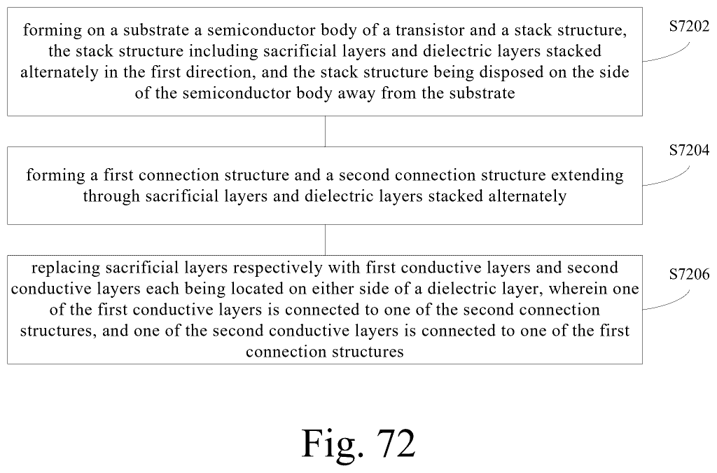

Referring back to FIG. 31, in some implementations, the method further includes: forming a second semiconductor structure 120; and hybrid bonding the first semiconductor structure 10 to the second semiconductor structure 120. The first connection structure 402 is led out as a common electrode 1202. In some implementations, the second semiconductor structure 120 has complementary metal oxide semiconductor 1204 including peripheral circuits. Hybrid bonding (also referred to as “metal/dielectric hybrid bonding”) is a direct bonding technology (e.g., bonding is formed between surfaces without an intermediate layer (e.g., solder or adhesive)), and metal-metal (e.g., copper-copper) bonding and dielectric-dielectric (e.g., silicon oxide-silicon oxide) bonding may be obtained simultaneously. Data transfer between the memory cell array in the second semiconductor structure and the peripheral circuits in the second semiconductor structure 120 may be performed via interconnection (e.g., the bonding contacts) through the metal layer 110. FIGS. 32 to 70 show a fabrication process of a semiconductor device according to various implementations of the present disclosure. FIG. 72 shows a flow chart of a method of forming a semiconductor device according to some implementations of the present disclosure. The semiconductor device shown in FIGS. 32 to 70 and FIG. 72 includes the semiconductor device shown in FIGS. 6 and 7.

Referring to FIG. 72, a process of forming a first semiconductor structure in another method of forming a semiconductor device is provided, the process including the following operations.

In operation S7202, a semiconductor body of a transistor and an original stack structure are formed and the stack structure includes sacrificial layers and dielectric layers stacked alternately in the first direction.

In some implementations as shown in FIG. 32, a semiconductor body 302 and an original stack structure 180 are formed on a substrate 130, the original stack structure 180 includes sacrificial layers 182 and dielectric layers 206 stacked alternately in the first direction, and the substrate 130 may include silicon (e.g., single crystal silicon, c-Si), silicon germanium (SiGe), gallium arsenide (GaAs), germanium (Ge), silicon on insulator (SOI) or any other suitable material.

In some implementations, the sacrificial layers 182 and the dielectric layers 206 may be formed alternately using a variety of thin film deposition processes such as CVD, PVD, ALD and the like, and the dielectric layers 206 may include a dielectric material including, but not limited to, silicon oxide, silicon nitride, silicon oxynitride or any combination thereof. Sacrificial layers 182 may be insulating layers including any suitable insulating material that has an etching rate different from that of the material of the dielectric layers 206 during one or more selective etching processes. In some implementations, sacrificial layers 182 include silicon nitride.

In some implementations as shown in FIG. 32, in the process of forming the semiconductor body 302, a third sacrificial layer 184 parallel to the original stack structure 180 is further formed.

When the original stack structure is taken as a whole, one end of the original stack structure is the upper surface, the other end of the original stack structure is close to the semiconductor body 302 and disposed parallel to the third sacrificial layer 184 relatively, and dielectric is filled between the original stack structure and the third sacrificial layer 184.

In some implementations as shown in FIG. 32, the semiconductor body 302 may extend above the top surface of the substrate 130 and, as described with respect to a fabrication process, the semiconductor body 302 may be formed form the substrate (e.g., by etching or epitaxy) and thus have the same semiconductor material (e.g., crystalline silicon) as the substrate (e.g., a silicon substrate). In some implementations, in order to form the semiconductor body, an opening extending through a stack of dielectric layers is formed by etching to expose a part of the substrate and the semiconductor body grows epitaxially from the exposed part of the substrate in the opening. The process of fabricate the semiconductor body 302 through epitaxial growth may include, but not limited to, vapor-phase epitaxy (VPE), liquid-phase epitaxy (LPE), molecular-beam epitaxy (MPE) or any combination thereof. Epitaxy may be performed upward (toward the positive z direction) from the exposed part of the substrate 130 in the opening. The semiconductor body 302 may have the same shape as the opening, such as a cube shape or a cylinder shape dependent on the shape of the opening.

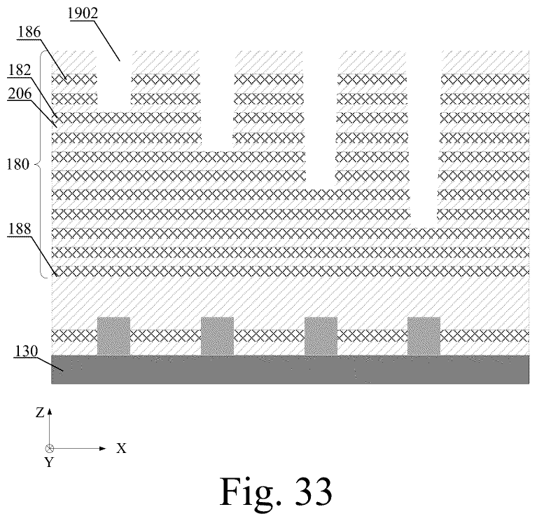

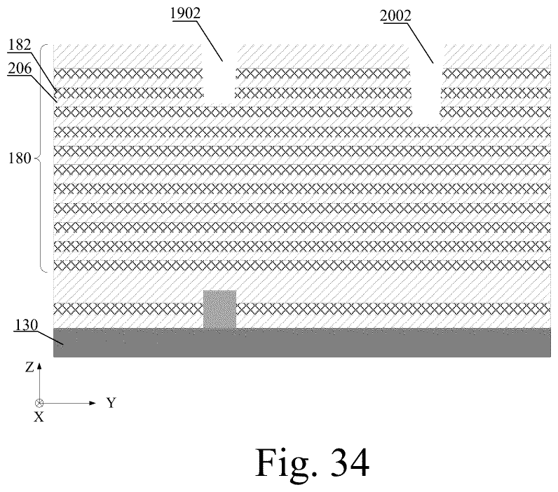

Referring back to FIG. 72, the method further includes operation S7204, in which a first connection structure and a second connection structure extending through sacrificial layers and dielectric layers stacked alternately are formed. In some implementations, the first connection structure and the second connection structure may be formed synchronously. When an array of first connection structures 404 and second connection structures 50 as shown in FIG. 7 is formed, first connection holes and second connection holes need to be formed first, each first connection hole including a first sub-hole and a second sub-hole and each second connection hole including a third sub-hole and a fourth sub-hole. As shown in FIGS. 33 and 34, first sub-holes 1902 and third sub-holes 2002 may be formed respectively in an original stack structure 180 and stop alternately at different sacrificial layers 182. In some implementations, a plurality of columns of first sub-holes 1902 and a plurality of columns of third sub-holes 2002 are formed in the second direction (the x direction), each column of first sub-holes 1902 and each column of third sub-holes 2002 are arranged in the third direction (the y direction) respectively, and each column of connection holes stop at the same sacrificial layer 182.

In some implementations, the uppermost layer, a first layer 186, the sacrificial layer 182 therebelow and a dielectric layer 206 etc. of the original stack structure 180 are etched successively through patterning and etching using photolithography and an etching process to form first sub-holes 1902 and third sub-holes 2002 with the first sub-holes 1902 being in alignment with semiconductor bodies. In some implementations, photolithography is performed using an etch mask (e.g., a photoresist mask) to pattern openings for connections holes based on a design for word lines and bit lines, and one or more dry etching and/or wet etching processes (e.g., reactive ion etching (RIE)) are performed to etch through sacrificial layers 182 and dielectric layers 206.

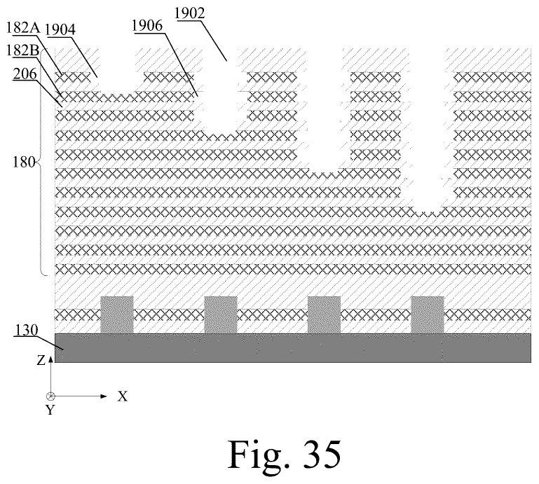

In some implementations as shown in FIG. 35, a fourth recess 1904 is formed at the portion of the sidewall of the first sub-hole 1902 belonging to the sacrificial layer 182A and a fifth recess 1906 is formed at the portion of the sidewall belonging to the sacrificial layer 182B. In some implementations, a sacrificial layer 182 is etched off through the first sub-hole 1902. For example, wet etchant may be applied through the first sub-hole 1902 to etch the sacrificial layer 182 selectively by wet etching to form the fourth recess 1904 and the fifth recess 1906.

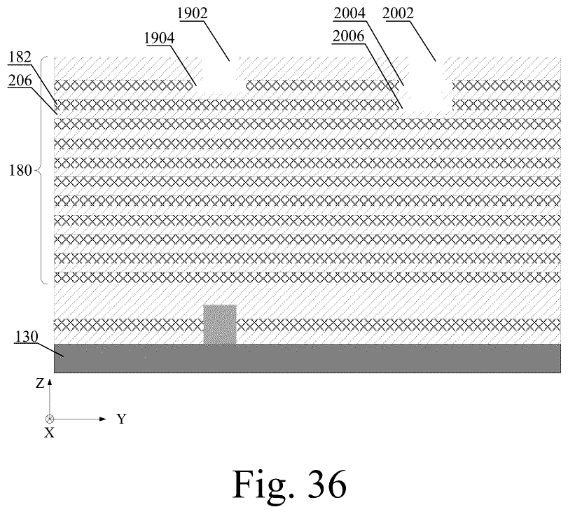

In some implementations as shown in FIG. 36, a sixth recess 2004 is formed at the portion of the sidewall of the third sub-hole 2002 belonging to the sacrificial layer 182A, and a seventh recess 2006 is formed at the portion of the sidewall belonging to the sacrificial layer 182B. In some implementations, sacrificial layers 182 are etched off through the third sub-hole 2002. For example, wet etchant may be applied through the third sub-hole 2002 to etch the sacrificial layers 182 selectively by wet etching to form the sixth recess 2004 and the seventh recess 2006.

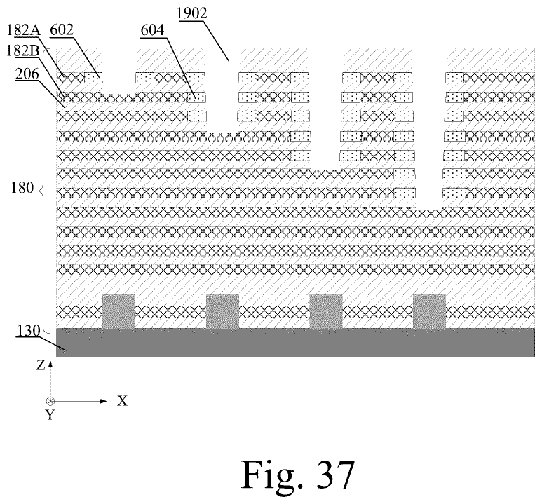

In some implementations as shown in FIG. 37, a first isolation layer 602 is deposited in the fourth recess 1904 to isolate the structure in the hole from the sacrificial layer 182A, and a second isolation layer 604 is deposited in the fifth recess 1906 to isolate the structure in the hole from the sacrificial layer 182B, so that when sacrificial layers are replaced by conductive layers and the second connection structure is formed, the second connection structure is isolated from the conductive layers.

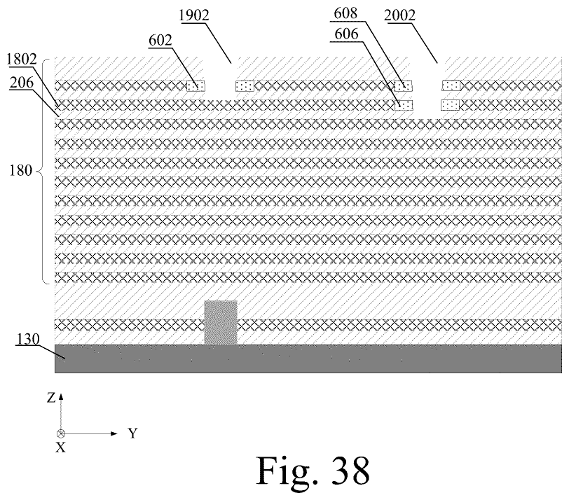

In some implementations as shown in FIG. 38, a fourth isolation layer 608 is deposited in the sixth recess 2004 to isolate the structure in the hole from the sacrificial layer 182A, and a third isolation layer 606 is deposited in the seventh recess 2006 to isolate the structure in the hole from the sacrificial layer 182B, so that when sacrificial layers are replaced by conductive layers and the first connection structure are formed, the first connection structure is isolated from the conductive layers.

For example, the deposition process includes chemical vapor deposition (CVD), physical vapor deposition (PVD), atomic layer deposition (ALD) or the like.

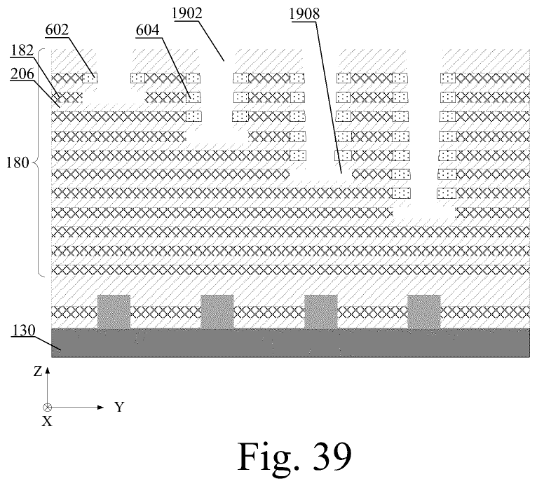

In some implementations as shown in FIG. 39, a second bottom recess 1908 is formed in the sacrificial layer 182B, at which the first sub-hole 1902 stops. In some implementations, the sacrificial layer 182 at the bottom is etched off through the first sub-hole 1902. For example, wet etchant may be applied through the first sub-hole 1902 to etch the sacrificial layer 182 selectively by wet etching.

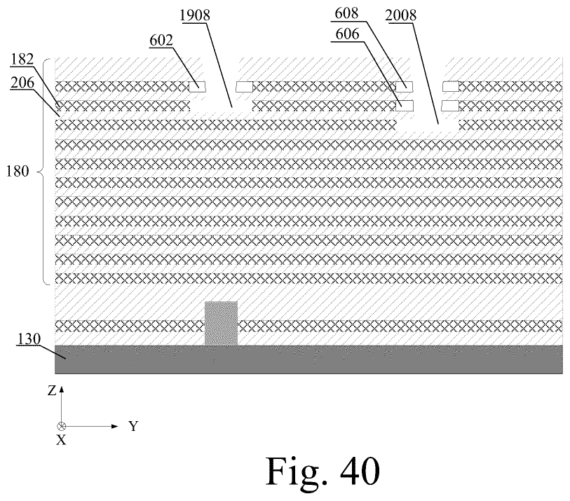

In some implementations as shown in FIG. 40, a third bottom recess 2008 is formed in the sacrificial layer 182A, at which the third sub-hole 2002 stops. In some implementations, the sacrificial layer 182 at the bottom is etched off through the third sub-hole 2002. For example, wet etchant may be applied through the third sub-hole 2002 to etch the sacrificial layer 182 selectively by wet etching.

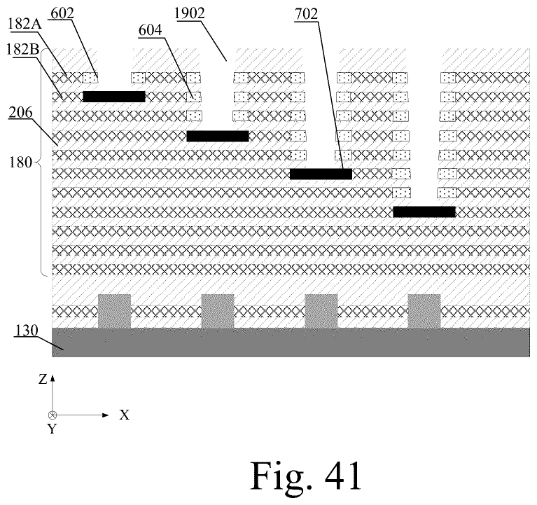

In some implementations as shown in FIG. 41, a conductive material is deposited in the second bottom recess 1908 to form a first communication component 702 in contact with the first sacrificial layer 182B, and for example the deposition of the conductive material may include depositing the conductive material through one or more thin film deposition processes, including, but not limited to, chemical vapor deposition (CVD), physical vapor deposition (PVD), atomic layer deposition (ALD), plating, electroless plating or any combination thereof.

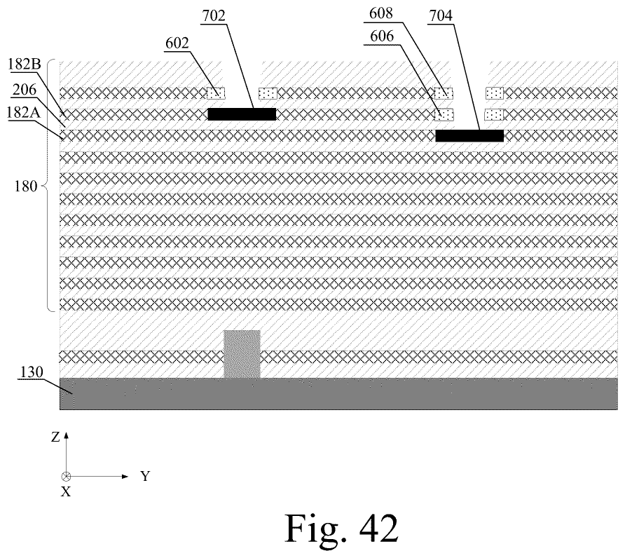

In some implementations as shown in FIG. 42, a conductive material is deposited in the third bottom recess 2008 to form a second communication component 704 in contact with the first sacrificial layer 182A, and for example the deposition of the conductive material may include depositing the conductive material through one or more thin film deposition processes, including, but not limited to, chemical vapor deposition (CVD), physical vapor deposition (PVD), atomic layer deposition (ALD), plating, electroless plating or any combination thereof.

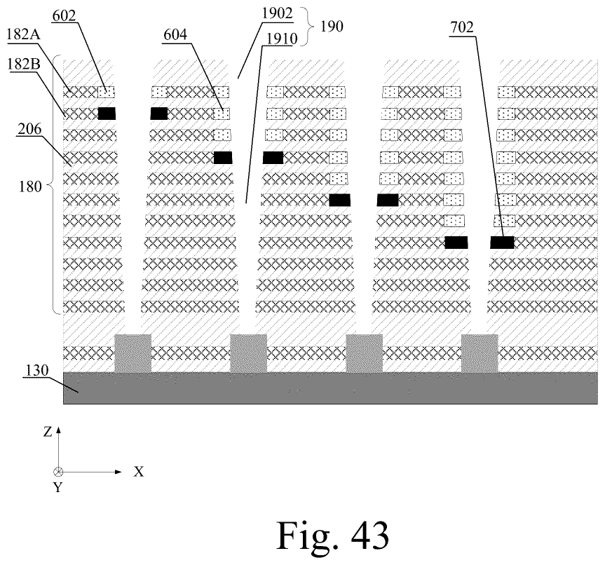

In some implementations as shown in FIG. 43, a second sub-hole 1910 is formed to extend through the first communication component 702 to the semiconductor body along the first direction. The first sub-hole 1902 and the second sub-hole 1910 are in communication with each other to form a first connection hole 190.

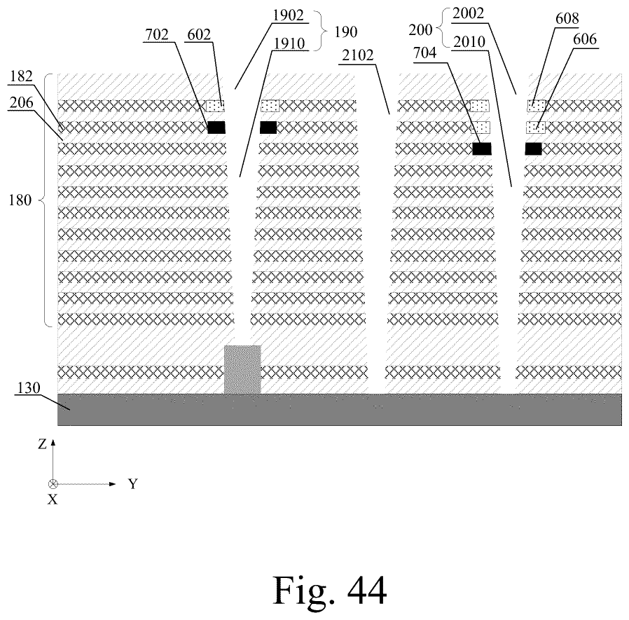

In some implementations as shown in FIG. 44, during the process of forming the second sub-hole 1910, the synchronization further includes: forming a fourth sub-hole 2010 extending through the second communication component 704 to the substrate 130 in the first direction, the third sub-hole 2002 being in communication with the fourth sub-hole 2010 to form a second connection hole 200. In some implementations, during the process of forming the second sub-hole 1910, the synchronization further includes: forming an original slit 2102 that extends through the original stack structure in the first direction and stops at the substrate 130. In some implementations, the original slit 2102 is patterned and etched using photolithography and an etching process.

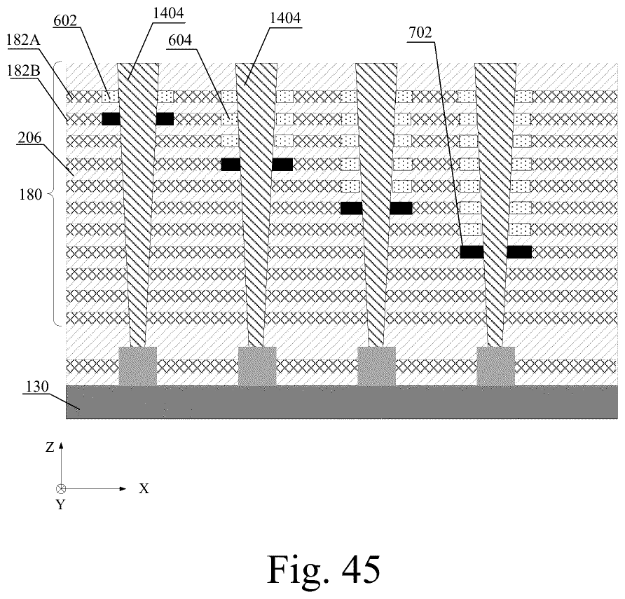

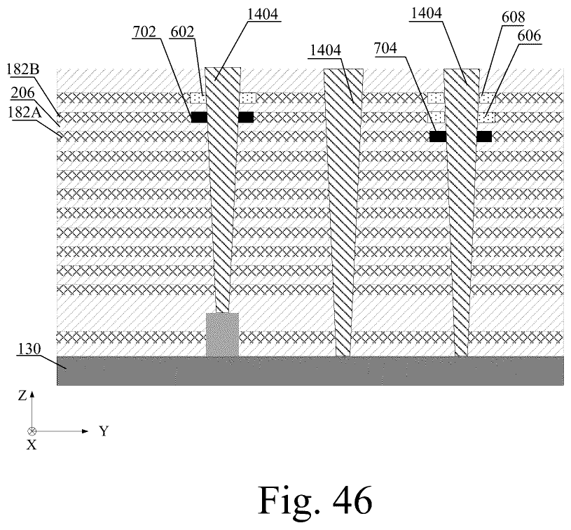

In some implementations as shown in FIG. 45, the method further includes: depositing a second sacrificial layer 1404 into the first connection hole 190. In some implementations, the second sacrificial layer 1404 may be formed using any suitable deposition process, such as CVD, PVD, ALD or the like, followed by a chemical mechanical polishing (CMP) process. In some implementations as shown in FIG. 46, the method further includes: depositing a second sacrificial layer 1404 into the second connection hole 200 and the original slit 2102. In some implementations, the second sacrificial layer 1404 may be formed using any suitable deposition process, such as CVD, PVD, ALD or the like, followed by a chemical mechanical polishing (CMP) process.

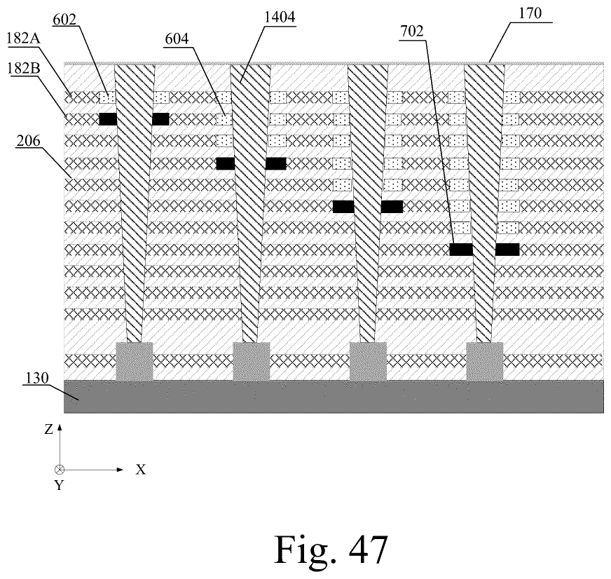

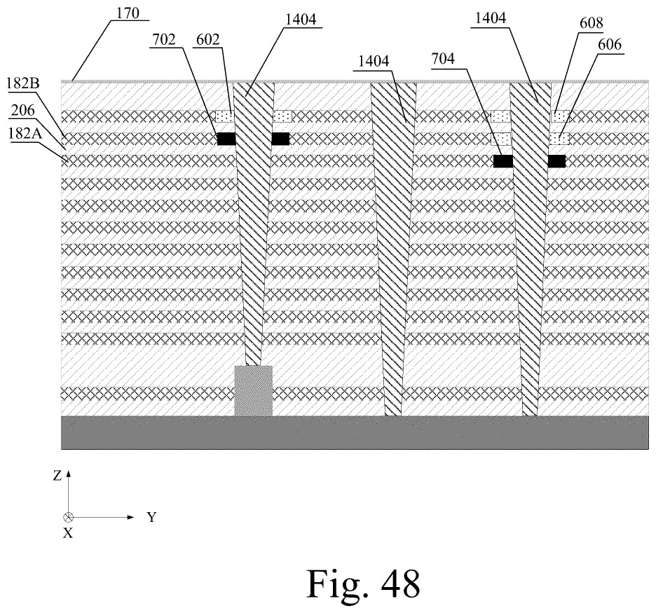

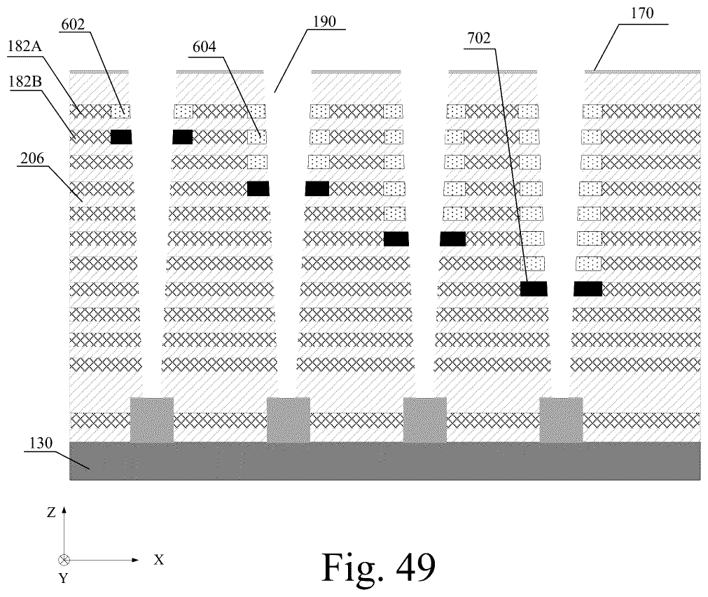

As shown in FIGS. 47 and 48, in some implementations, the method further includes: a protecting layer 170 is formed on the end of the original stack structure 180 away from the substrate 130. The protecting layer 170 is further etched to expose the ends of the first connection hole 190 and second connection hole 200 filled with the second sacrificial layer 1404. In some implementations, a second connection structure is formed after removing the second sacrificial layer 1404 deposited in the connection hole. In some implementations as shown in FIG. 49, the second sacrificial layer 1404 in the first connection hole 190 is removed.

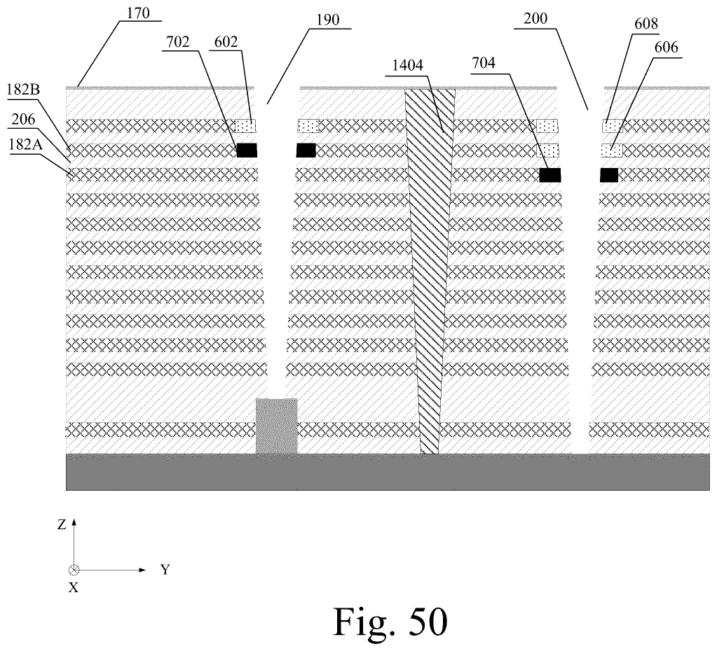

In some implementations as shown in FIG. 50, the second sacrificial layer 1404 in the second connection hole 200 is removed.

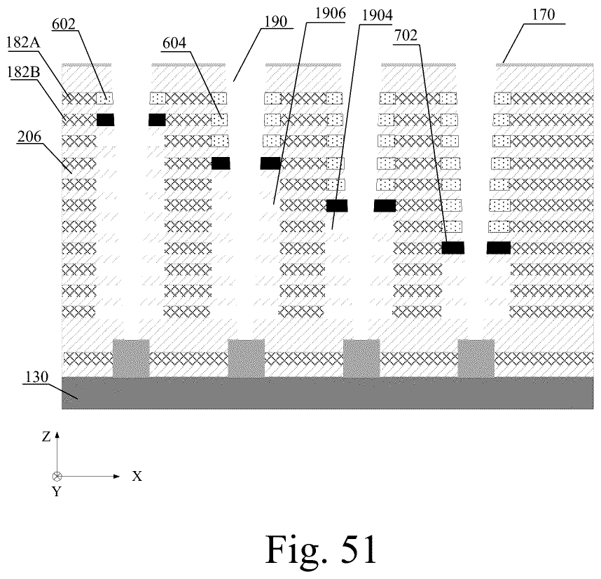

In some implementations as shown in FIG. 51, a fourth recess 1904 is formed at the portion of the sidewall of the second sub-hole 1910 belonging to the sacrificial layer 182A and a fifth recess 1906 is formed at the portion of the sidewall belonging to the sacrificial layer 182B. In some implementations, sacrificial layers 182 are removed through the second sub-hole 1910. For example, wet etchant may be applied through the second sub-hole 1910 to etch the sacrificial layers 182 selectively by wet etching to form the fourth recess 1904 and the fifth recess 1906.

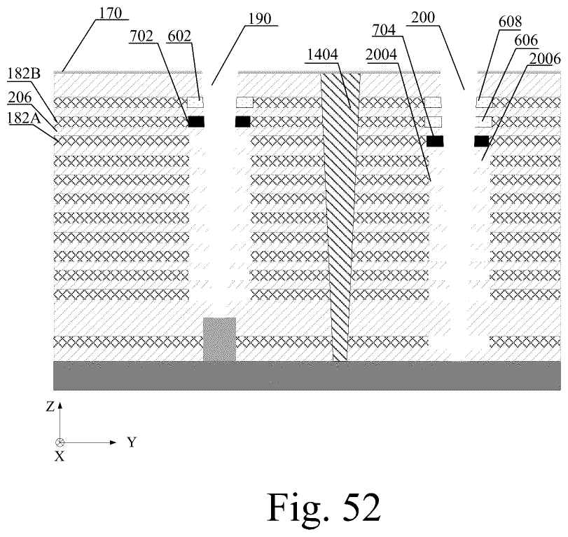

In some implementations as shown in FIG. 52, a sixth recess 2004 is formed at the portion of the sidewall of the fourth sub-hole 2010 belonging to the sacrificial layer 182A and a seventh recess 2006 is formed at the portion of the sidewall belonging to the sacrificial layer 182B. In some implementations, sacrificial layers 182 are etched off through the fourth sub-hole 2010. For example, wet etchant may be applied through the fourth sub-hole 2010 to etch the sacrificial layers 182 selectively by wet etching to form the sixth recess 2004 and the seventh recess 2006.

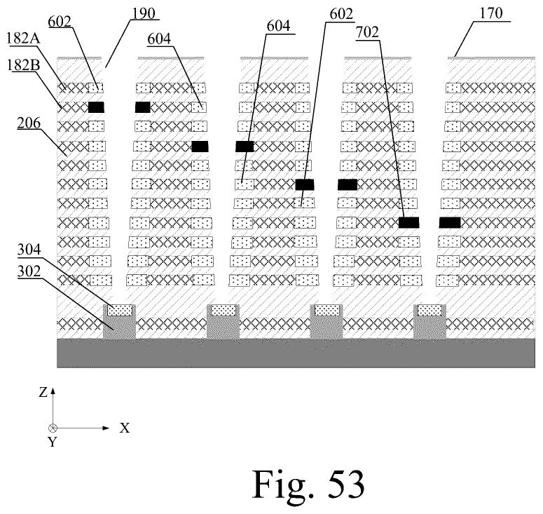

In some implementations as shown in FIG. 53, a first isolation layer 602 is deposited in the fourth recess 1904 to isolate the structure in the hole from the sacrificial layer 182A and a second isolation layer 604 is deposited in the fifth recess 1906 to isolate the structure in the hole from the sacrificial layer 182B, so that when sacrificial layers are replaced by conductive layers and the second connection structure is formed, the second connection structure is isolated from the conductive layers.

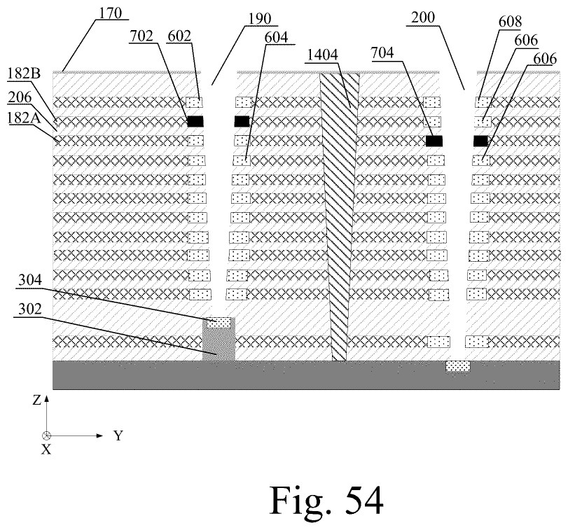

In some implementations as shown in FIG. 54, a fourth isolation layer 608 is deposited in the sixth recess 2004 to isolate the structure in the hole from the sacrificial layer 182A, and a third isolation layer 606 is deposited in the seventh recess 2006 to isolate the structure in the hole from the sacrificial layer 182B, so that when sacrificial layers are replaced by conductive layers and the first connection structure are formed, the first connection structure is isolated from the conductive layers.

For example, the deposition process includes chemical vapor deposition (CVD), physical vapor deposition (PVD), atomic layer deposition (ALD) or the like.

In some implementations as shown in FIGS. 53 and 54, at least one of an implantation process or a thermal diffusion process is performed through the first connection hole 190 to dope P-type dopant or N-type dopant into the exposed upper end of the semiconductor body 302 and in turn form a source/drain, i.e. a first electrode 304. In some implementations, a silicide layer is formed on the first electrode by performing a silicidation process on the exposed upper end of the semiconductor body.

In some implementations, an oxide (OX) material may be used as the insulating material, may be formed using atomic layer deposition (ALD) and may be aluminum oxide (Al₂O₃).

In some implementations as shown in FIGS. 53 and 54, the method further includes: removing the protecting layer 170.

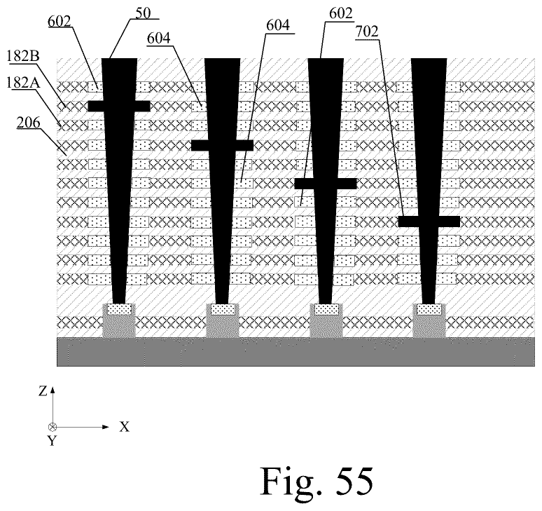

In some implementations as shown in FIG. 55, the method further includes: forming a second connection structure 50 connected to one sacrificial layer 182B and the first electrode 304 in the first connection hole 190. The second connection structure 50 is connected to the first communication component 702 in the horizontal direction via the lateral sides so as to be connected to the horizontal sacrificial layer 182B. The end of the second connection structure is connected to the first electrode 304 and in turn to the transistor. After replacing the sacrificial layers 182B with a first conductive layer, electrical connection is further achieved between the first conductive layer in a planar capacitor and the transistor. In some implementations, a deposition process such as CVD, PVD, ALD or the like may be performed to deposit W in the first connection hole 190. Then chemical mechanical polishing is done on the deposited W to form the second connection structure 50.

In some implementations as shown in FIG. 56, the method further includes: forming a first connection structure 404 connected to a sacrificial layer 182A in the second connection hole 200. The first connection structure 404 is connected to the second communication component 704 in the horizontal direction via the lateral sides so as to be connected to the horizontal sacrificial layer 182A. The end of the first connection structure 404 extends to the substrate 130. After replacing the sacrificial layer 182A with a second conductive layer, electrical connection is further achieved between second conductive layers in planar capacitors. In some implementations, a deposition process such as CVD, PVD, ALD or the like may be performed to deposit W in the second connection hole 200. Then chemical mechanical polishing is done on the deposited W to form the second connection structure 50.

Referring back to FIG. 72, the method further includes operation S7206, in which sacrificial layers are replaced by first conductive layers and second conductive layers each being located on either side of a dielectric layer, wherein a first conductive layer is connected to a second connection structure, and a second conductive layer is connected to a first connection structure.

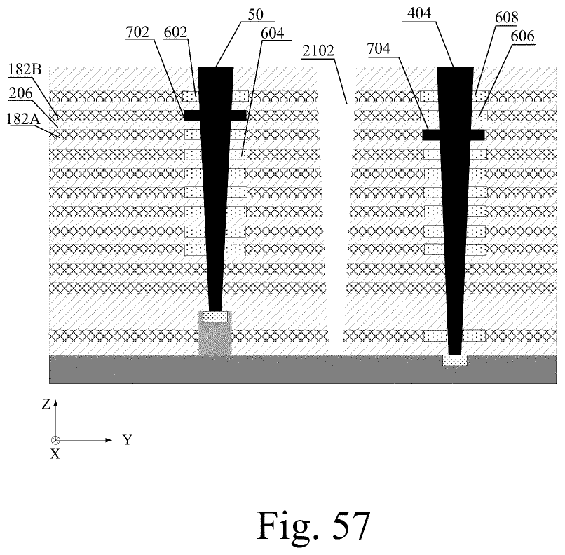

After forming the first connection structure 404 and the second connection structure 50, as shown in FIGS. 56 and 57, the second sacrificial layer 1404 is removed to form the original slit 2102 again.

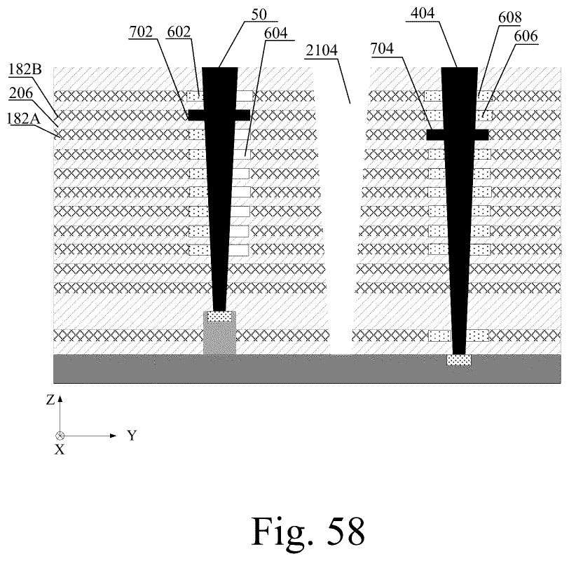

Further, the original slit 2102 needs to be expanded. Since the sacrificial layers 182 and the dielectric layers 206 may both be insulating layers, the hole expansion may be achieved by etching the insulating layers. As shown in FIG. 58, after etching of the insulating layers is finished, an intermediate slit 1604 is formed to expose the sacrificial layers 182 and the third sacrificial layer 184.

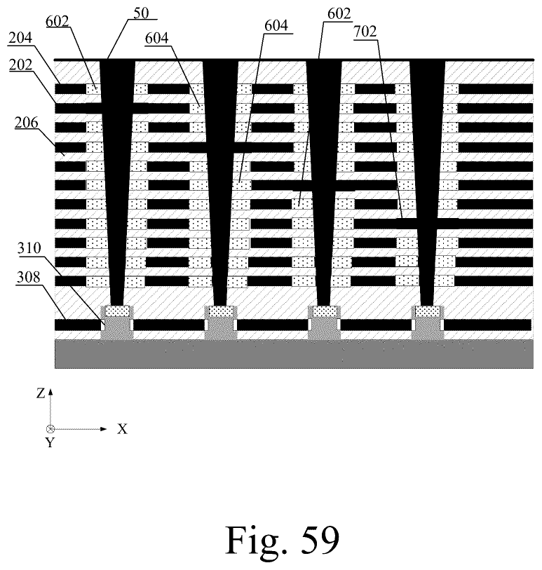

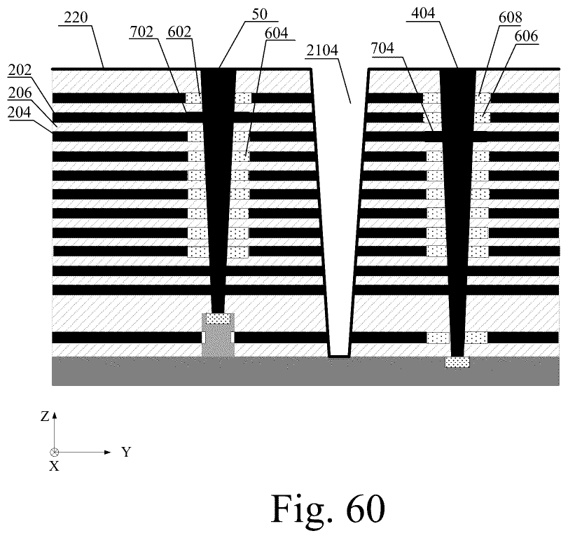

As shown in FIGS. 59 and 60, there are exposed portions of the first sacrificial layers and the third sacrificial layer at the sidewalls of the intermediate slit 2104. The sacrificial layers are removed to form horizontal trenches (not shown in the figure). The first conductive layers, the second conductive layers and the gate layer 308 are formed in the horizontal trenches through the exposed portions, a first conductive layer 202 is connected to a first electrode 304 through a first communication component 702 and a second connection structure 50, and second conductive layers 204 are connected through a second communication component 704 and a first connection structure 404. As shown in FIG. 60, during the process of forming the first conductive layers 202 and the second conductive layers 204, a conductive material 220 is formed on the upper surface of the stack structure.

Furthermore, after forming the first conductive layers 202 and the second conductive layers 204, the original stack structure 180 is converted into the stack structure.

As shown in FIG. 59, the method further includes forming a gate dielectric layer 310. In some implementations, after removing the third sacrificial layer 1806, the sidewalls of the semiconductor body 302 are exposed and oxidized to form the gate dielectric layer 310. The gate dielectric layer 310 may join the corresponding semiconductor body 302 fully. In some implementations, at least one of a wet oxidization process or a dry oxidization process (e.g., ISSG) may be performed to form native oxide (e.g., silicon oxide) on the semiconductor body 302 (e.g., single crystal silicon) as the gate dielectric 310. In some implementations, a dielectric layer (e.g., silicon oxide) is deposited on the exposed portions of the semiconductor body 302 using one or more thin film deposition processes (including, but not limited to, CVD, PVD, ALD or any combination thereof) to form the gate dielectric layer 310.

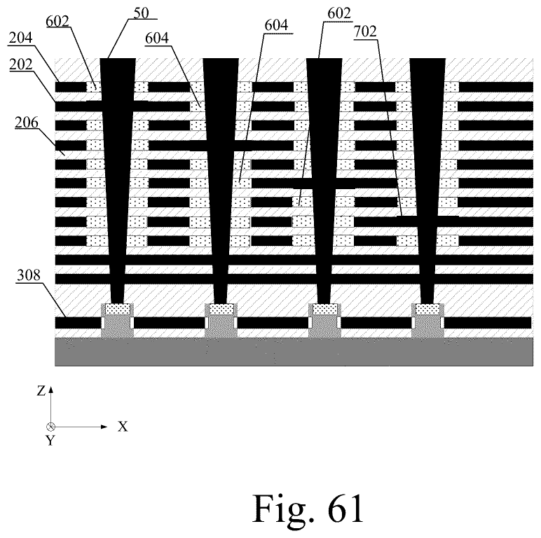

As shown in FIG. 61, the conductive material 220 on the surface of the stacked layers is removed.

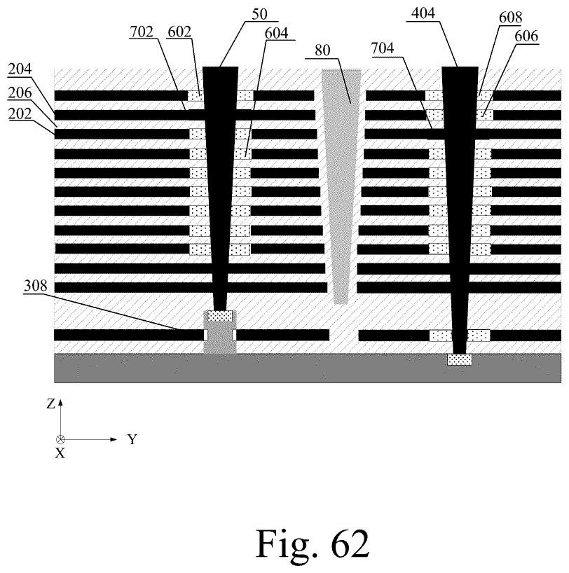

In some implementations as shown in FIG. 62, the method further includes: filling the intermediate slit 2104 to form an isolation structure 80. In some implementations, the isolation structure 80 includes, but not limited to, W, Co, Cu, Al, polysilicon, doped silicon, silicide or any combination thereof. Or it can be POLY, conductive metal or a metal compound, for example, the conductive layers may be W layers or POLY layers.

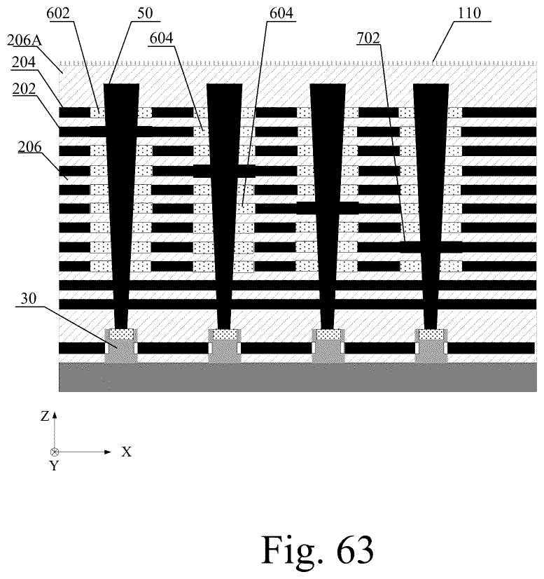

In some implementations as shown in FIG. 63, after forming the isolation structure 80, in order to cover the exposed surfaces of the first connection structure 404, the second connection structure 50 and the isolation structure 80, in some implementations, a dielectric layer 206A may be formed through a plurality of thin film deposition processes such as CVD, PVD, ALD and the like to cover the exposed surfaces.

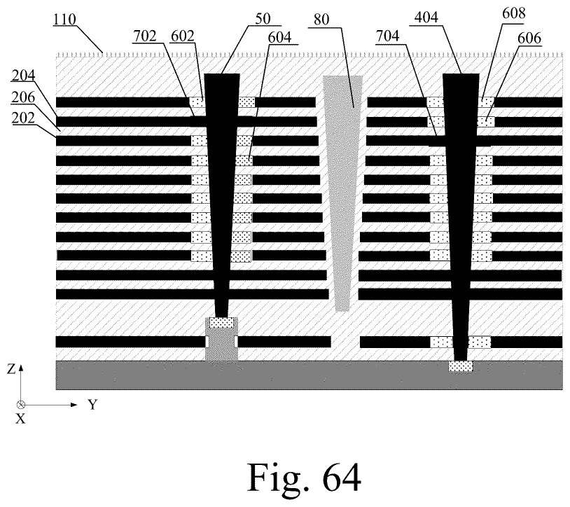

Referring to FIG. 64, the method further includes: depositing a metal layer 110 on the side of the stack structure away from the transistors as a bonding interface. In some implementations, the metal layer 110 may serve as the bonding interface for the bonding with the second semiconductor structure. The bonding interface may be a layer of a certain thickness including the top surface of the bonding layer of the second semiconductor structure and the bottom surface of the bonding layer of the first semiconductor structure.

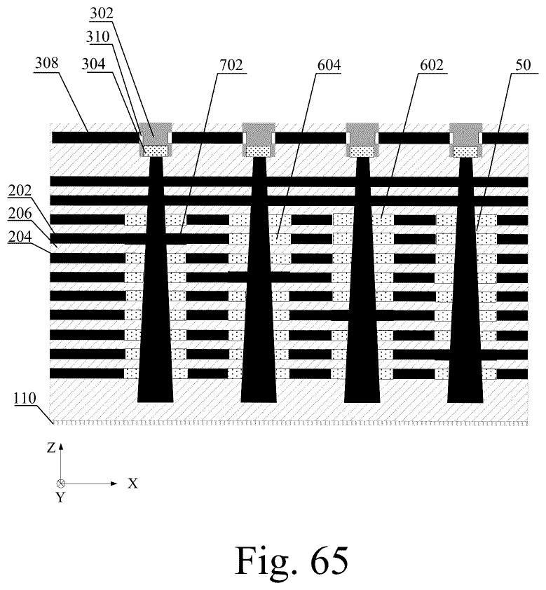

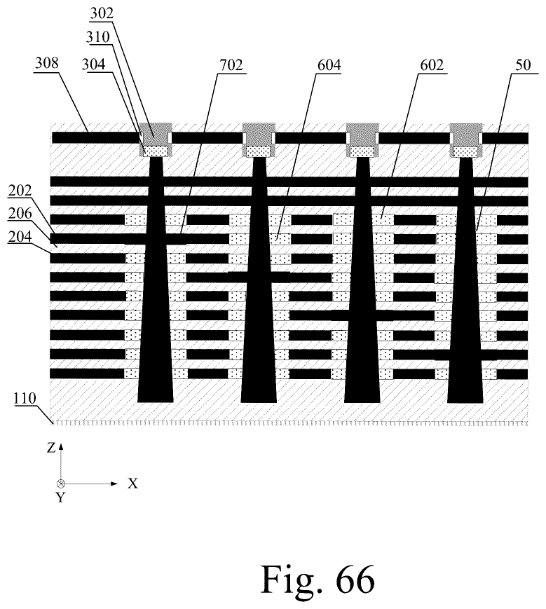

In some implementations, as shown in FIGS. 65 and 66, the method further includes: removing the substrate 130 on the side of the semiconductor body away from the stack structure to expose the surface of the semiconductor body 302.

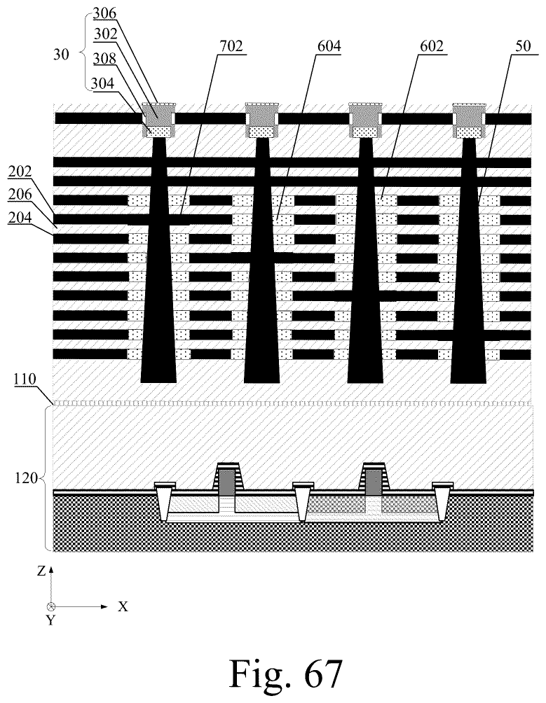

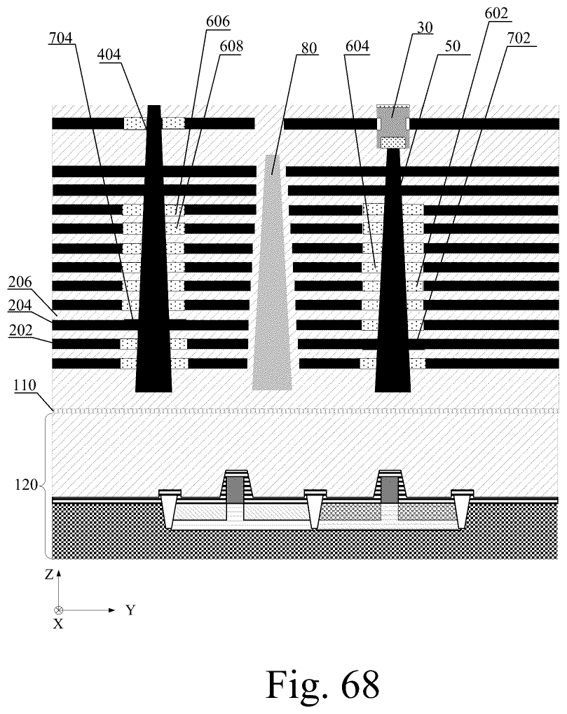

In some implementations, at the exposed end of the semiconductor body 302, a second electrode 306 is formed to be connected to a bit line 100 and serves as the other of the source and the drain of a transistor. As shown in FIGS. 67 and 68, exposed upper end of each semiconductor body 302 (i.e. the one of the two ends of the semiconductor body 302 in the vertical direction (the z direction) away from the carrier substrate 130) is doped to form the other of source/drain, i.e. the second electrode 306. In some implementations, at least one of an implantation process or a thermal diffusion process is performed to dope P-type dopant or N-type dopant into the exposed upper end of the semiconductor body 302 and in turn form the second electrode 306. In some implementations, a silicide layer is formed on the second electrode 306 by performing a silicidation process on the exposed upper end of the semiconductor body 302. In some implementations, thereby a vertical transistor 30 including the semiconductor body 302, the source/drain 304 and 306, the gate layer 308 and the gate dielectric 310 is formed. Here, the second electrode 306 is connected to a bit line 100 and the gate layer 308 is connected to a word line 90.

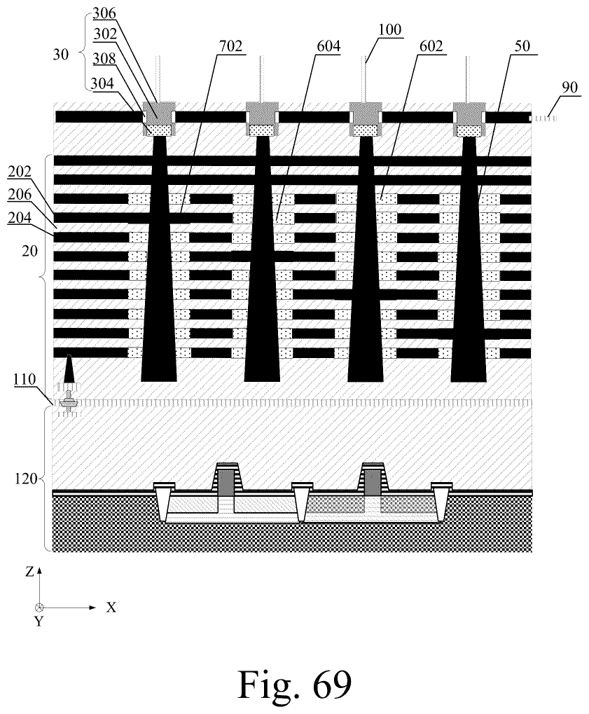

Referring back to FIGS. 69 and 70, in some implementations, the method further includes: forming a second semiconductor structure 120; and hybrid bonding the first semiconductor structure 10 to the second semiconductor structure 120. The first connection structure 404 is led out as a common electrode 1202. In some implementations, the second semiconductor structure 120 has complementary metal oxide semiconductor 1204 including peripheral circuits. Hybrid bonding (also referred to as “metal/dielectric hybrid bonding”) is a direct bonding technology (e.g., bonding is formed between surfaces without an intermediate layer (e.g., solder or adhesive)), and metal-metal (e.g., copper-copper) bonding and dielectric-dielectric (e.g., silicon oxide-silicon oxide) bonding may be obtained simultaneously. Data transfer between the memory cell array in the second semiconductor structure and the peripheral circuits in the second semiconductor structure 120 may be performed via interconnection (e.g., the bonding contacts) through the metal layer 110.

A memory system according to one implementation of the present disclosure includes a semiconductor device and a controller, wherein the semiconductor device includes: a first semiconductor structure including a stack structure, a transistor and a first connection structure, wherein the stack structure includes first conductive layers and second conductive layers stacked alternately in a first direction, the transistor is disposed on one side of the stack structure and connected with one of the first conductive layers, and the first connection structure extends through the stack structure in the first direction and is connected to the second conductive layers; and a bit line and a word line connected to the transistor respectively, wherein the controller is coupled to the semiconductor device and configured to control the semiconductor device.

In some implementations, the stack structure includes a plurality of second conductive layers connected to the same first connection structure. The first connection structure is a slit structure extending in a third direction perpendicular to the first direction.

In some implementations, the first semiconductor structure includes a plurality of sets of the first connection structures, the stack structure includes a plurality of the second conductive layers, and each of the second conductive layers is connected to one set of the first connection structures. The first connection structures may each be a pillar structure.

In some implementations, the stack structure further includes: dielectric layers each located between a first conductive layer and a second conductive layer.

The dielectric layer may include a dielectric material including, but not limited to, silicon oxide, silicon nitride, silicon oxynitride or any combination thereof.

In some implementations, each dielectric layer 108 has a same nominal thickness between about 15 nm and about 30 nm, for example, a thickness between 15 nm and 30 nm, such as 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, any range bounded any one of the values as a lower limit or any range bounded by any two of the values.

In this implementation, a first conductive layer, a dielectric layer and a second conductive layer form a planar capacitor configured for storage of charges or data. A connection structure extending longitudinally through the whole stack structure enables one side of the planar capacitor to serve as a common electrode and enables the first conductive layer as the other side of the planar capacitor to be connected to a transistor.

In some implementations, the first semiconductor structure further includes: a second connection structure extending through the stack structure in the first direction and connected to the first conductive layers and the transistor respectively.

In some implementations, the first connection structure is a slit structure extending in a third direction perpendicular to the first direction and a plurality of second connection structures form an array structure.

In some implementations, the first semiconductor structure includes a plurality of sets of the first connection structures. A plurality of first connection structures alternates with a plurality of second connection structures in the y direction.

Here, each second connection structure may be a pillar structure or a plate-like structure.

In some implementations, the stack structure includes a plurality of first conductive layers and each of the first conductive layers is connected to a second connection structure.

Here, in a memory cell architecture having a plurality of conductive layers, there may be one or more second connection structures or one or more sets of second connection structures. In an architecture with only one second connection structure or one set of second connection structures, a plurality of first conductive layers may be connected to a second connection structure or one of the first conductive layers is connected a second connection structure respectively.

In some implementations, the stack structure includes a plurality of first conductive layers and each of the first conductive layers is connected to a second connection structure.

In some implementations, a plurality of sets of second connection structures are included and each set of second connection structures are connected to one of first conductive layers respectively.

In some implementations, the stack structure includes a plurality of second conductive layers connected to the same first connection structure.

Here, in a stack structure having a plurality of sets of first conductive layers, dielectric layers and second conductive layers, one second connection structure or one set of second connection structures is only connected to one of the first conductive layers. Therefore, with respect to one second connection structure or one set of second connection structures and for a first conductive layer with a connection relationship therewith, a first communication component needs to be formed at periphery in the horizontal direction and connected to the first conductive layer, while for the first conductive layers and the second conductive layers without any connection relationship therewith, insulating components need to be formed at periphery. Illustratively, an insulating component disposed between a second connection structure and a second conductive layer is designated as a first isolation layer and an insulating component disposed between a second connection structure and one of the first conductive layers isolated from each other is designated as a second isolation layer.

In some implementations, the first connection structure is a slit structure extending in the third direction perpendicular to the first direction.

In some implementations, a plurality of sets of the first connection structures are included, the stack structure includes a plurality of second conductive layers, and each of the second conductive layers is connected to one set of the first connection structures.

In some implementations, the transistor includes a vertical transistor, which includes a semiconductor body extending in the first direction and a source and a drain disposed on the two sides of the semiconductor body in the first direction; one of the source and the drain is connected to the first conductive layer; and the other of the source and the drain is connected to the bit line.

In some implementations, the vertical transistor further includes a gate in contact with at least one side of the semiconductor body, and the word line is connected to the gate along the second direction perpendicular to the first direction.

In some implementations, the stack structure further includes: a metal layer disposed on the other side of the stack structure away from the transistor.

In some implementations, it further includes: a second semiconductor structure located on the side of the first semiconductor structure away from the transistor and hybrid bonded with the first semiconductor structure.

Moreover, the present application further provides a memory system. The memory system includes the semiconductor device of at least one of the implementations described above and a controller electrically connected with a memory, i.e. the logic control unit in the following description, wherein the logic control unit is also connected to an external host. The external host may transmit user instructions and data for storage to the logic control unit. The user instructions may include write instructions, erase instructions and read instructions. The logic control unit may determine the storage position in the semiconductor device, at which writing, erasing and reading will be performed according to the contents.

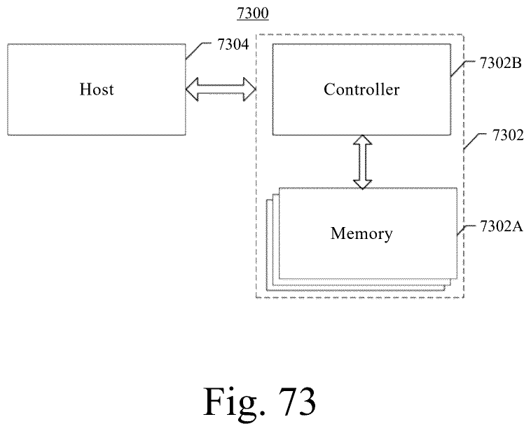

For example, FIG. 73 is a block diagram of a memory system in an implementation of the present disclosure. The memory system 7300 may be a mobile phone, a desktop computer, a laptop computer, a tablet computer, a vehicle computer, a game console, a printer, a locating apparatus, a wearable electronic apparatus, a smart sensor, a virtual reality (VR) apparatus, an augmented reality (AR) apparatus and any other suitable electronic apparatus having a memory therein. As shown in FIG. 73, the memory system 7300 may include a host 7304 and a memory subsystem 7302 that includes one or more memories 7302A and a controller 7302B with the memory 7302A including a memory cell array and a plurality of page buffers. The host 7304 can be a processor of an electronic device such as a central processing unit (CPU), or a system-on-chip (SoC) such as an application processor (AP). The host 7304 may be configured to send data to the memory 7302A or receive data from the memory 7302A.

The semiconductor device in the present disclosure may be a memory 7302A or a part thereof. According to some implementations, the controller 7302B is coupled to the memory 7302A and the host 7304 and configured to control the memory. The controller 7302B may manage the data stored in the memory and communicate with the host 7304. In some implementations, the controller 7302B is designed for operating in a low duty-cycle environment like a secure digital (SD) card, a compact flash (CF) card, a universal serial bus (USB) flash drive, or any other medium for use in an electronic device such as a personal computer, a digital camera, a mobile phone, etc. In some implementations, the controller 7302B is designed for operating in a high duty-cycle environment like an SSD or an embedded multi-media-card (eMMC), used as a data storage for a mobile device such as a smart phone, a tablet computer or a laptop computer, and an enterprise storage device. The controller 7302B can be configured to control operations of the memory 7302A, such as read, crase, and program operations. The controller 7302B can also be configured to manage various functions with respect to the data stored or to be stored in the memory 7302A, including, but not limited to bad-block management, garbage collection, logical-to-physical address conversion, wear leveling, and the like. In some implementations, the controller 7302B is further configured to process error correction codes (ECCs) with respect to the data read from or written to the memory 7302A. Any other suitable functions can be performed by the controller 7302B as well, for example, formatting the memory 7302A. The controller 7302B can communicate with an external device (e.g., the host 7304) according to a particular communication protocol. For example, the controller 7302B may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The controller 7302B and the one or more memories 7302A can be integrated into various types of storage devices, for example, be included in the same package, such as a universal flash (UFS) or an eMMC package. That is, the memory subsystem 7302 can be implemented and packaged into different types of terminal electronics.

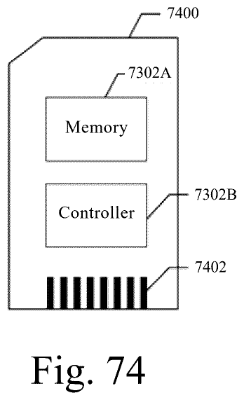

FIG. 74 is a schematic diagram of a memory card provided in an implementation of the present disclosure. In an example as shown in FIG. 74, the controller 7302B and a single memory 7302A can be integrated into a memory card 7400. The memory card 7400 may include a PC card (PCMCIA, personal computer memory card international association), a CF card, a smart media (SM) card, a memory stick, a multimedia card (MMC, RS MMC, MMCmicro), an SD card (SD, miniSD, microSD, SDHC), a UFS, etc. The memory card 7400 may further include a memory card connector 7402 coupling the memory card 7400 with a host (e.g., the host 1008 in FIG. 74).

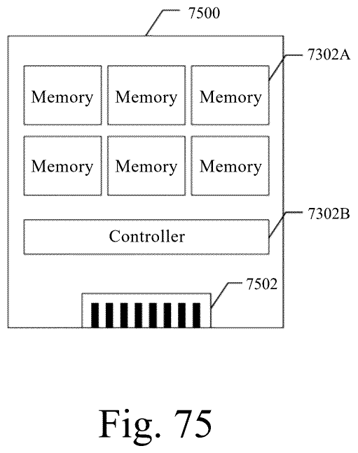

FIG. 75 is a schematic diagram of a solid state drive (SSD) provided in an implementation of the present disclosure. As shown in FIG. 75, the controller 7302B and a plurality of memories 7302A can be integrated into an SSD 7500. The SSD 7500 may also include an SSD connector 7502 coupling the SSD 7500 and the host (e.g., the host 1004 in FIG. 73). In some implementations, the memory capacity and/or operating speed of the SSD 7500 are greater than the memory capacity and/or operating speed of the memory card 7400.

It is to be noted that the structures of the memories described above are only illustrative structures and the operating method of the present application is also applicable to other types of memories or memories of other structures.

The foregoing description of the implementations will so fully reveal the general nature of the present disclosure that others can, by applying knowledge within the skill of the art, readily modify and/or adapt, for various applications, such implementations, without undue experimentation, and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the those skilled in the art in light of the disclosure and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternative boundaries can be defined so long as the specified functions and relationships thereof are appropriately performed.

The Summary and Abstract sections can set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A semiconductor device, comprising a first semiconductor structure that comprises:
a stack structure and a transistor, wherein the stack structure comprises first conductive layers and second conductive layers stacked alternately in a first direction, and the transistor is on one side of the stack structure and connected with one of the first conductive layers; and
a first connection structure extending through the stack structure in the first direction and connected to the second conductive layers.

2. The semiconductor device of claim 1, wherein the stack structure further comprises:
dielectric layers between the first conductive layers and the second conductive layers.

3. The semiconductor device of claim 1, wherein the first semiconductor structure further comprises:
a second connection structure extending through the stack structure in the first direction and respectively connected to the first conductive layers and the transistor.

4. The semiconductor device of claim 3, wherein the stack structure further comprises:
first isolation layers between the second connection structure and the second conductive layers.

5. The semiconductor device of claim 3, comprising a plurality of sets of second connection structures, each set of second connection structures being connected to a respective one of the first conductive layers.

6. The semiconductor device of claim 1, wherein the stack structure comprises at least two of the second conductive layers connected to the first connection structure.

7. The semiconductor device of claim 6, wherein the first connection structure is a slit structure extending in a second direction perpendicular to the first direction.

8. The semiconductor device of claim 1, comprising a plurality of sets of first connection structures, wherein the stack structure comprises a plurality of second conductive layers, each of the plurality of second conductive layers being connected to a respective set of first connection structures.

9. The semiconductor device of claim 8, wherein the first semiconductor structure further comprises:
an isolation structure extending through the stack structure in the first direction and extending in a second direction perpendicular to the first direction.

10. The semiconductor device of claim 1, wherein the transistor comprises a vertical transistor that comprises a semiconductor body extending in the first direction and a gate layer in contact with at least one side of the semiconductor body.

11. The semiconductor device of claim 1, further comprising:
a metal layer disposed on another side of the stack structure away from the transistor.

12. The semiconductor device of claim 1, further comprising:
a second semiconductor structure located on a side of the first semiconductor structure away from the transistor and integrated with the first semiconductor structure by hybrid bonding.

13. A method of forming a semiconductor device, comprising:
forming a first semiconductor structure, comprising:
forming a semiconductor body of a transistor and a stack structure, wherein the stack structure comprises first sacrificial layers, first dielectric layers, second conductive layers, and second dielectric layers that are stacked alternately in a first direction;
forming a first electrode on the semiconductor body, the first electrode being one of a source and a drain of the transistor;
replacing the first sacrificial layers with first conductive layers, one of the first conductive layers being connected to the first electrode; and
forming a first connection structure connected to the second conductive layers and
extending through the stack structure.

14. The method of claim 13, wherein forming the first electrode on the semiconductor body comprises:
forming a connection hole extending through the stack structure to the semiconductor body in the first direction;
forming first isolation layers and second isolation layers at an inner wall of the connection hole, wherein the first isolation layers isolate the second conductive layers, and the second isolation layers isolate the first sacrificial layers without connection relationship; and
forming, in the connection hole, a second connection structure respectively connected to one of the first sacrificial layers and the first electrode.

15. The method of claim 14, wherein forming the connection hole extending through the stack structure to the semiconductor body in the first direction comprises:
forming an original slit extending through the stack structure in the first direction.

16. The method of claim 15, wherein, before forming, in the connection hole, the second connection structure connected to one of the first sacrificial layers and the first electrode respectively, the method further comprises:
depositing a second sacrificial layer in the connection hole and the original slit.

17. The method of claim 16, wherein forming, in the connection hole, the second connection structure connected to one of the first sacrificial layers and the first electrode respectively comprises:
removing the second sacrificial layer deposited in the connection hole and filling the
connection hole to form the second connection structure.

18. A memory system, comprising:
a semiconductor device; and
a controller,
wherein the semiconductor device comprises a first semiconductor structure comprising a stack structure, a transistor and a first connection structure, wherein the stack structure comprises first conductive layers and second conductive layers stacked alternately along a first direction, the transistor is disposed on one side of the stack structure and connected with one of the first conductive layers, and the first connection structure extends through the stack structure in the first direction and is connected to the second conductive layers; and
a bit line and a word line connected to the transistor respectively,
wherein the controller is coupled to the semiconductor device and configured to control the semiconductor device.

19. The memory system of claim 18, wherein the stack structure further comprises:
dielectric layers between the first conductive layers and the second conductive layers.

20. The memory system of claim 18, wherein the first semiconductor structure further comprises:
a second connection structure extending through the stack structure in the first direction and connected to the first conductive layers and the transistor, respectively.
